(19) United States
(12) Patent Application Publication
(10) Pub. No.: US 2006/0198174 A1
(43) Pub. Date: Sep. 7, 2006

(54) Contents Providing System, Output Control Device, and Output Control Program

(76) Inventors: Yuji Sato, Nagoya-shi, Aichi-ken (JP); Kazuma Aoki, Nagoya-shi, Aichi-ken (JP); Masatoshi Kokubo, Nagoya-shi, Aichi-ken (JP); Satoru Yanagi, Nagoya-shi, Aichi-ken (JP)

Correspondence Address: BAKER BOTTS LLP;C/O INTELLECTUAL PROPERTY DEPARTMENT, THE WARNER, SUITE 1300, 1299 PENNSYLVANIA AVE, NW, WASHINGTON, DC, 20004-2400, US

(21) Appl. No.: 11/276,261

(22) Filed: Feb. 21, 2006

(30) Foreign Application Priority Data
Feb. 21, 2005 (JP) 2005-044347
Feb. 21, 2005 (JP) 2005-044348

(51) Int. Cl. G11C 15/00

(52) U.S. Cl. 365/49

(57) ABSTRACT

A contents providing system is provided with an information obtaining unit that obtains at least one of input information input to a user interface of a client device and output information output from the user interface, a content searching unit that searches for contents in accordance with the information obtained by the information obtaining unit, a content output control unit that outputs a content searched by the content searching unit to an output unit, the output unit providing the content to a user of the client device, and a content identifying unit that identifies one of the contents searched by the content searching unit, each of the contents having executed a predetermined process, the content identifying unit identifies the content that has executed the predetermined process latest. Further, the contents output control unit outputs the content identified by the content identifying unit prior to other contents searched by the content searching unit.

### CROSS-REFERENCE TO RELATED APPLICATION

This application is related to Japanese Patent Applications No. 2005-044347 and No. 2005-044348, both filed on Feb. 21 2005, the entire subject matter of which is incorporated herein by reference.

### BACKGROUND

1. Technical Field

Aspects of the invention relate to a contents providing system configured to provide contents to a user of a client device, an output control device employed in the contents providing system and a program therefor.

2. Description of Related Art

Recently, contents providing systems have been suggested. The contents providing system is typically configured such that, based on an user's input via a user interface, the contents providing system searches for contents which the user may be interested in, and outputs the thus searched contents via the user interface or a display unit and the like.

An example of such a contents providing system is disclosed in Japanese Patent Provisional Publication No. 2004-164678 (hereinafter, referred to as '678 publication). Specifically, the '678 publication discloses a system which acquires a speech by a user through a microphone, applies a voice recognition, and extracts a keyword from the recognized speech. Then, the system searches for contents based on the keyword, and outputs the search results to a display unit.

According to the '678 publication, however, the searched contents are sequentially output. Therefore, it takes a relatively long time to output all the searched contents. Further, even contents which the user may not be interested in will be displayed when it is detected. Since all the contents, including such unnecessary ones, are displayed, other contents which the user may be interested in would not be displayed at an earlier stage. That is, the necessary contents may not be displayed at appropriate timings according to the prior art.

### SUMMARY OF THE INVENTION

Aspects of the invention are advantages in that a technique enabling the contents providing system to provide contents which the user may be interested in at an appropriate timing (i.e., without unnecessary delay).

### BRIEF DESCRIPTION OF THE ACCOMPANYING DRAWINGS

FIG. 1 is a block diagram showing a configuration of an entire contents providing system according to aspects of the invention.

FIG. 2 shows an example of a contents providing window including a plurality of display areas.

FIG. 3 is a flowchart illustrating a PC investigating procedure according to aspects of the invention.

FIG. 4 is a flowchart illustrating a telephone investigating procedure according to aspects of the invention.

FIG. 5 is a flowchart illustrating a source information registration procedure according to aspects of the invention.

FIG. 6 shows a data structure of a source management table according to aspects of the invention.

FIG. 7 is a flowchart illustrating a keyword extracting procedure according to aspects of the invention.

FIG. 8 shows a data structure of a searched information management table according to aspects of the invention.

FIG. 9 is a flowchart illustrating a search controlling procedure according to aspects of the invention.

FIG. 10 shows a data structure of a search program table according to aspects of the invention.

FIG. 11 shows a flowchart illustrating a searching procedure according to aspects of the invention.

FIG. 12 shows a data structure of a search result management procedure according to aspects of the invention.

FIG. 13 shows a flowchart illustrating a retrieval control procedure according to aspects of the invention.

FIGS. 14A-14C show data structures of term display table, reproduction table and text/image display table, respectively.

FIG. 15 shows a flowchart illustrating first and second output control procedure according to aspect of the invention.

FIGS. 16A-16D show data structures of a term display list and text/image display list according to aspects of the invention.

FIG. 17 shows a flowchart illustrating a third output control procedure according to aspects of the invention.

FIG. 18 shows a flowchart illustrating a search control procedure according to aspects of a second embodiment of the invention.

FIG. 19 shows a data structure of a search program table according to aspects of the second embodiment of the invention.

FIG. 20 shows a flowchart illustrating a searching procedure according to aspects of the second embodiment of the invention.

FIG. 21 shows a data structure of a search result management table according to aspects of the second embodiment of the invention.

FIG. 22 shows a flowchart illustrating a read control procedure according to aspects of the second embodiment of the invention.

FIG. 23 shows a flowchart illustrating a readout procedure according to aspects of the second embodiment.

FIG. 24 shows a flowchart illustrating an output procedure according to aspects of the second embodiment.

FIG. 25 shows a flowchart illustrating a search control procedure according to aspects of a third embodiment of the invention.

FIG. 26 shows a flowchart illustrating a readout procedure according to aspects of a fourth embodiment of the invention.

FIG. 27 shows a data structure of a readout information management table according to aspects of the fourth embodiment of the invention.

### DETAILED DESCRIPTION

General Overview

It is noted that various connections are set forth between elements in the following description. It is noted that these connections in general and unless specified otherwise, may be direct or indirect and that this specification is not intended to be limiting in this respect. Aspects of the invention may be implemented in computer software as programs storable on computer-readable media including but not limited to RAMs, ROMs, flash memory, EEPROMs, CD-media, DVD-media, temporary storage, hard disk drives, floppy drives, permanent storage, and the like.

According to aspects of the invention, there is provided a contents providing system that provides contents. The system is provided with an information obtaining unit that obtains at least one of input information input to a user interface of a client device and output information output from the user interface, a content searching unit that searches for contents in accordance with the information obtained by the information obtaining unit, a content output control unit that outputs a content searched by the content searching unit to an output unit, the output unit providing the content to a user of the client device, and a content identifying unit that identifies one of the contents searched by the content searching unit, each of the contents having executed a predetermined process, the content identifying unit identifies the content that has executed the predetermined process latest. Further, the content output control unit outputs the content identified by the content identifying unit prior to other contents searched by the content searching unit.

The output unit may include a display unit, and the content output control unit may display the content searched by the content searching unit on the display unit to provide the content to the user of the client device.

The content output control unit may display the content identified by the content identifying unit differently from the other contents searched by the content searching unit.

The content output control unit may display the contents searched by the content searching unit on the display such that the contents are arranged in an order in which execution of the predetermined process is latest to earliest.

The contents providing system may further include a keyword extracting unit that extracts a keyword from the information obtained by the information obtaining system. The contents searching unit may search for contents corresponding to the keyword extracted by the keyword extracting unit.

The identifying unit may identify, among the contents searched by the content searching unit, a content from which a keyword was extracted by the keyword extraction unit latest.

The contents providing system may include time registering system configured to register a time when the predetermined process is executed during a process in which the contents searching unit searches the content in association with the content The content identifying unit identifies the content corresponding to the time, which is registered by the time registering system, is closest to the current time.

According to further aspects of the invention, there is provided an output control device, which includes a content output control unit that outputs a content which has been searched in accordance with a user's operation to provide the content to the user, and a content identifying unit that identifies, from among the contents searched in accordance with the user's operation, a content to which the identifying operation is performed at a later order than the other contents. The content output control unit may output the content identified by the content identifying unit prior to any other content searched in accordance with the user's operation.

According to aspects of the invention, there is provided a computer program product comprising computer readable instructions that cause a computer to execute the steps of obtaining at least one of input information with respect to a user interface provided to a client device and output information output by the user interface, searching for contents corresponding to the information obtained by the obtaining step, outputting the contents searched by the searching step to the output unit to provide the contents to the user of the client device, and identifying a content for which identifying operation is executed later than the identifying operation for other contents from among the contents searched by the searching step. The outputting step may output the content identified by the identifying step prior to other contents searched by the searching step.

According to aspects of the invention, there is provided a contents providing system, which is provided with an information obtaining unit that obtains at least one of input information input to a user interface of a client device and output information output from the user interface, a search procedure starting unit that subsequently starts searching procedures to search a predetermined database for contents corresponding to information obtained by the information obtaining unit, a content output control unit that outputs a content searched by the search procedure starting unit to an output unit, the output unit providing the content to a user of the client device, and a stopping unit that stops at least one search procedure that was started earliest among executed search procedures when the information obtaining unit obtains the information and a predetermined number or more of search procedures are being executed.

The search procedures starting unit may start, form among a plurality of kinds of the search procedures, one corresponding to the information obtained by the information obtaining unit, and the stopping unit may stop at least one search procedure that was started earliest among executed search procedures when the information obtaining unit obtains the information and a predetermined number or more of search procedures of the same kind are being executed.

The predetermined number may vary depending on the kinds of search procedures.

According to aspects of the invention, there is provided as contents providing system, which includes an information obtaining unit that obtains at least one of input information input to a user interface of a client device and output information output from the user interface, a search procedure starting unit that subsequently starts searching procedures to search a predetermined database for contents corresponding to information obtained by the information obtaining unit, a content output control unit that outputs a content searched by the search procedure starting unit to an output unit, the output unit providing the content to a user of the client device, an elapsed time investigating unit that investigates, for each of the searching procedure, an elapsed time after the searching procedure was started, and a stopping unit that stops the searching procedure of which the elapsed time is equal to or greater than a predetermined period.

The stopping unit may stop the searching procedure if the investigated elapsed time is equal to or greater than the predetermined period when the information obtaining unit obtains a subsequent piece of information.

The search procedure starting unit may start one of a plurality of types of the search procedures corresponding to the information obtained by the information obtaining unit, and the predetermined period may vary depending on the type of the search procedure.

According to aspects of the invention, there is provide a search control device for an output control device configured to include an information obtaining unit that obtains at least one of input information input to a user interface of a client device and output information output from the user interface, a search procedure starting unit that subsequently starts searching procedures to search a predetermined database for contents corresponding to information obtained by the information obtaining unit, a content output control unit that outputs a content searched by the search procedure starting unit to an output unit, the output unit providing the content to a user of the client device. The search control device may include a stopping unit that stops at least one search procedure that was started earliest among executed search procedures when the information obtaining unit obtains the information and a predetermined number or more of search procedures are being executed.

According to aspects of the invention, there is provided a search control device for an output control device including an information obtaining unit that obtains at least one of input information input to a user interface of a client device and output information output from the user interface, a search procedure starting unit that subsequently starts searching procedures to search a predetermined database for contents corresponding to information obtained by the information obtaining unit, and a content output control unit that outputs a content searched by the search procedure starting unit to an output unit, the output unit providing the content to a user of the client device. The search control device may include an elapsed time investigating unit that investigates, for each of the searching procedure, an elapsed time after the searching procedure was started, and a stopping unit that stops the searching procedure of which the elapsed time is equal to or greater than a predetermined period.

According to aspects of the invention, there is provided a computer program product comprising a computer readable instructions that cause a computer to execute the steps of obtaining unit that obtains at least one of input information input to a user interface of a client device and output information output from the user interface, subsequently starting searching procedures to search a predetermined database for contents corresponding to information obtained by the information obtaining step, outputting a content searched to an output unit, the output unit providing the content to a user of the client device, and stopping at least one search procedure that was started earliest among executed search procedures when the information obtaining step obtains the information and a predetermined number or more of search procedures are being executed.

According to aspects of the invention, there is provided a computer program product comprising a computer readable instructions that cause a computer to execute the steps of obtaining at least one of input information input to a user interface of a client device and output information output from the user interface, subsequently starting searching procedures to search a predetermined database for contents corresponding to information obtained by the information obtaining step, outputting a content searched by the searching step to an output unit, the output unit providing the content to a user of the client device, investigating, for each of the searching procedure, an elapsed time after the searching procedure was started, and stopping the searching procedure of which the elapsed time is equal to or greater than a predetermined period.

### Embodiments

Referring to the accompanying drawings, illustrative embodiments of the present invention will be described in detail.

Configuration of Entire System

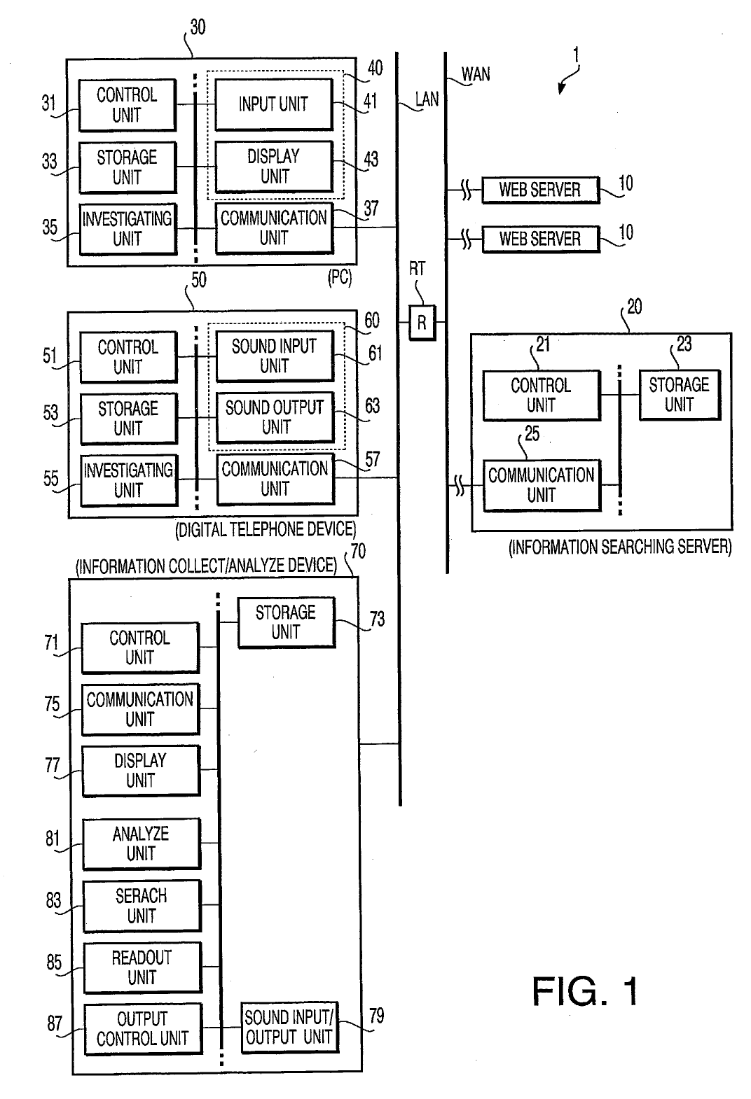

FIG. 1 shows a block diagram showing a contents providing system 1 according to aspects of the invention.

The contents providing system 1 includes, as shown in FIG. 1, one or more web servers 10 that have various contents to be provided and one or more information searching server 20, which are connected to a WAN (wide area network such as the Internet). The contents providing system 1 further includes at least one personal computer (PC) 30, a digital telephone device (hereinafter, simply referred to as a telephone) 50, and an information collecting/analyzing device 70, which are connected to a LAN (local area network). The LAN is connected to the WAN via a router R.

The information searching server 20 is provided with a control unit 21 including a CPU (Central Processing Unit), a ROM (Read Only Memory) and a RAM (Random Access Memory), not shown, a storage unit 23 including, for example, a hard disk drive (not shown) and a communication unit 25 which controls data communication between the WAN and the LAN.

The storage unit 23 stores a database containing address information (URL information) of various contents which the web server(s) 10 can provide, and various searching programs. One or more of the searching programs are executed when the information searching server 20 receives a query from an external device. The information searching server 20 (i.e., the control unit 21) searches for requested contents in accordance with the received query, and returns the search results to the source of the query (i.e., the external device that has issued the query).

The PC 30 includes a control unit 31 including a CPU, a ROM and a RAM (not shown), a storage unit 33 including, for example, a hard disk drive (not shown), an investigating unit 35 (described later), a communication unit 37 that controls data communication between the WAN and the LAN, a user interface 40 provided with an input unit 41 for acquiring user's input operation, and a display unit 43 for displaying various pieces of information.

In the storage unit 33, various pieces of application software (hereinafter, simply referred to as software) to be executed by the control unit 31 to realize various functions (e.g., generation of text data based on the text data input through the input unit 41, displaying of a text represented by the text data, etc.).

The investigation unit 35 investigates predetermined ones of the various pieces of software to be executed by the control unit 31 as target software, from which data is collected. The investigation unit 35 executes a procedure (i.e., a PC investigation procedure, which will be described later) for collecting the text input through the input unit 41 or displayed on the display unit 43 based on the software.

The telephone unit 50 includes a control unit 51 provided with a CPU, a ROM and a RAM (not shown), a storage unit 53 provided with a hard disk drive, an investigation unit 55, a communication unit 47 that controls data communication between the WAN and the LAN, a user interface 60 including a sound input unit 61 that receives a voice (audio) input (i.e., voice (audio) signal) and converts the voice (audio) signal to audio data and a sound output unit 63 that outputs voice (audio) wave represented by the audio data. The telephone device 50 is configured to function as an IP (Internet Protocol) telephone capable of being connected to an external telephone device via the WAN and the LAN.

The investigating unit 55 investigates the audio data which is exchanged via the user interface 60, and executes a procedure (i.e., a telephone investigation procedure, described later) for collecting the audio data.

The information collecting/analyzing device 70 includes a control unit 71 provided with a CPU, a ROM and a RAM (not shown), a storage unit 73 provided with a hard disk drive, etc., a communication unit 75 that controls a data communication between the WAN and the LAN, a display unit 77 for displaying various pieces of information, a sound output unit 79 configured to output a sound wave represented by the sound (audio) data, an analyzing unit 81, a searching unit 83, a reading unit 85 and an output control unit 87, which will be described later.

The storage device 73 stores various pieces of programs to be executed by the control unit 71, the analyzing unit 81, the searching unit 83, the reading unit 85 and the output control unit 87, and various data tables to be referred to when the above programs are executed.

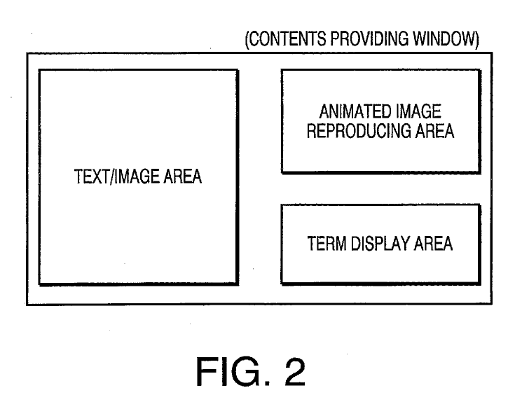

The display unit 77 operates to display a contents providing window as shown in FIG. 2. Specifically, the contents providing window contains a text/image area for displaying text/image which can be scrolled therein, an animation image playing area in which an animation image can be played, and a term display area for displaying a result of term searching.

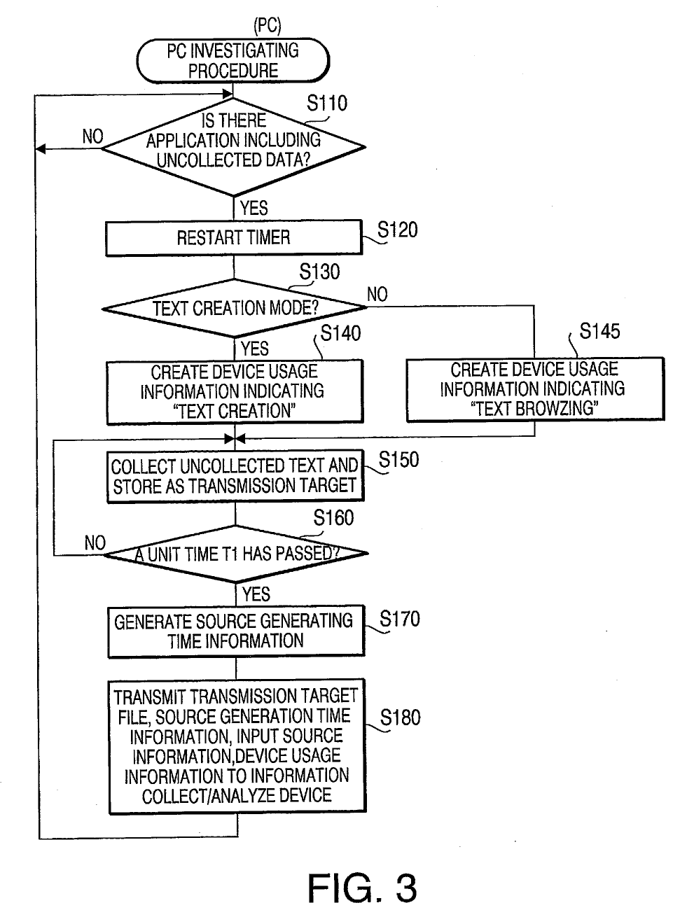

Next, a PC investigation procedure executed by the investigation unit 35 of the PC 30 will be described with reference to a flowchart shown in FIG. 3. The PC investigation procedure is repeatedly executed after the PC is started up.

When the PC investigation procedure is started, the control judges whether there exists software among a plurality of predetermined pieces of software retaining text data which has not yet being collected (S110).

If the control determines that such software does not exist (S110: NO), the control repeatedly executes S110 until at least one piece of the software retains uncollected text data. If the control determines that such software retaining the uncollected text data exists (S110: YES), the control resets a timer and restarts counting (i.e., measuring time) (S120).

Next, the control checks a text handling mode in which the software determined (in S110) to retain the uncollected text (S130). The text handling mode can be judged after a notification issued by the software is received when the control checked the software in S110. If the software is updating the contents displayed on the display unit 43 as well as the text data in response to input operation through the input unit 41, the text handling mode notified by the software is a “text creation mode”, while if a predetermined text (e.g., a text represented by text data designated using the input unit 41) is displayed on the display unit 43, the software notifies of a “text browse mode”. Thus, in S130, the control judges the text handling mode in accordance with the notification by the software.

When the control determines that the software is executed in the “text creation mode” (S130: YES), the control generates device usage information indicative of “text creation” (S140). If software is not executed in the “text creation mode” (i.e., is executed in the “text browse mode” (S130: NO), the control generates the device usage information indicative of the “text browse” (S145).

As above, after generating the device usage information, the control starts writing the text data as a transmission target file with collecting the uncollected text data from the software (S150). The writing process in S150 is continued until the count value of the timer, which was reset in S120, reaches a predetermined unit time T1 (which is one minute in the illustrative embodiment). That is, if the count value of the timer is less than T1 (S160: NO), the control returns S150. When the count value of the timer is T1 (S160: YES), the control proceeds to S170 and generates source generating time information representing the current time.

Then, the transmission target file containing the text data corresponding to the unit time period T1, the source generation time information generated in S170, the device usage information generated in S140 or S145, and the input source information indicating that the transmission source is the PC 30 are related to each other and then transmitted, as source information, to the information collect/analyze device 70 (S180). Then, the control returns to S110 and awaits occurrence of next uncollected data.

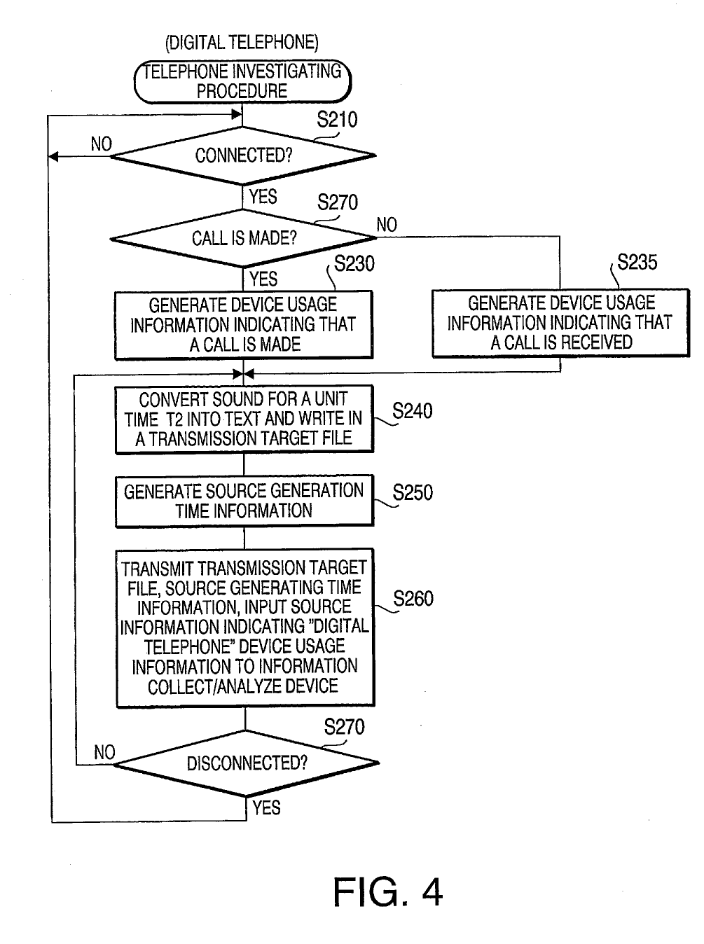

Next, a telephone investigation procedure executed by the investigation unit 55 of the telephone device 50 will be described referring to FIG. 4. It should be noted that the telephone investigation procedure is repeatedly executed after the telephone device 50 has been started up.

When the telephone investigation procedure is started, the control pauses until a connection between the telephone device 50 and another telephone device is established (i.e., the communication line is closed) (S210). That is, if the communication line is not closed (S210: NO), the control repeats S210. When the communication line is closed, that is, when the telephone device 40 is connected to another telephone device (S210: YES), the control judges whether the connection is made because the telephone device 50 has made a call (S220).

If the control determines that the connection is made since the telephone device 50 has made a call (S220: YES), the control generates the device usage information indicating a “calling status” (S230). If the control determines that the other device has made a call (i.e., the telephone device 50 has received a call) (S220: NO), the control generates the device usage information indicating a “called status” (S235).

After the device usage information has been generated as described above, before elapse of a unit time period T2, the control obtains the sound data input/output through the sound input unit 61 and sound output unit 63, converts the voice represented by the sound data into text data using a well-known voice recognition technique, and stores the text data in the transmission target file (S240).

Next, the control generates source generation time information indicating the current time (S250). Then, the transmission target file generated in S240, the source generation time information generated in S250, the device usage information generated in S230 or S235, and the input source information indicating that the transmission source is the telephone device are related to each other and transmitted to the information collect/analyze device 70 as the source information (S260).

After transmitting the source information S260, the control judges whether the connection is cut (i.e., the communication line is opened). If the connection has not been cut (S270: NO), the control returns to S240, and repeats the process of converting the sound data into text data for the succeeding time period of T2. If the control determines that the connection is cut (S270: YES), the control returns to S210 and waits for another connection (S210: NO).

Next, various procedures executed by the information collect/analyze device 70 will be described.

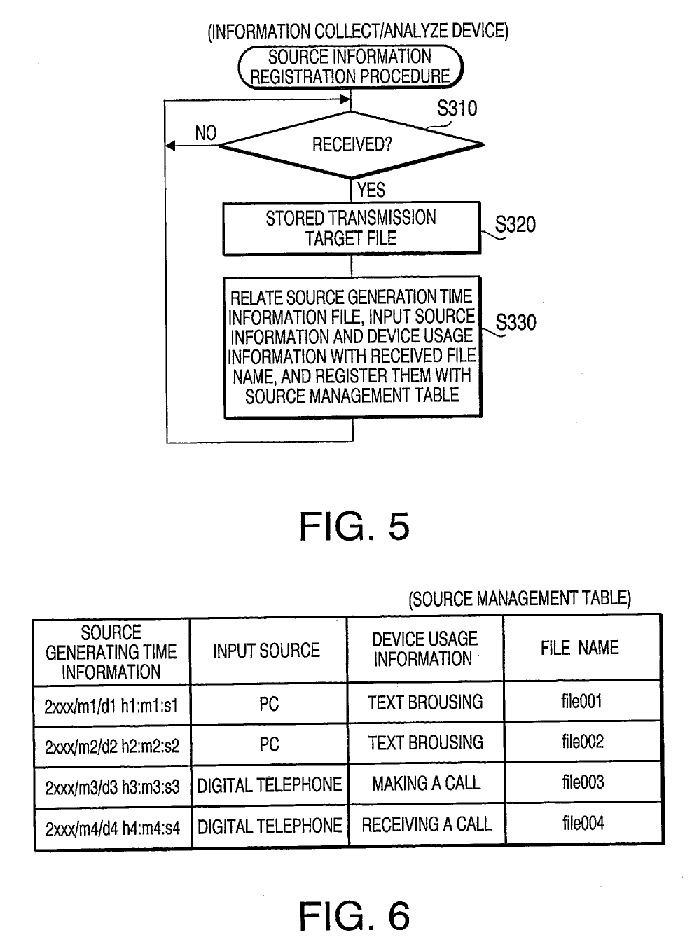

FIG. 5 shows a flowchart illustrating a source information registration procedure, which is repeatedly executed by the control unit 71 after the information collect/analyze device 70 has been started up.

When the source information registration procedure is executed, the control pauses until the source information transmitted from the PC 30 (FIG. 3: S180) or the source information transmitted from the telephone device 50 (FIG. 4: S260) is received. That is, until reception of the source information, decision in S310 is “NO”, and S310 is repeated.

When the source information is received (S310: YES), the transmission target file included in the source information is stored in the storage unit 73 as a file having a predetermined file name (S320).

Then, a record having the file name (or a path name) of the transmission target file stored in S320, the source generation time information included in the source information received in S310, the device usage information and the input source information is registered with the source management table (S330). Thereafter, the control returns to S310, and pauses until the next source information is received. It should be noted that, according to the illustrative embodiment, a record includes the source generation time information, the device usage information, the input source information which are related to the file name of the transmission target file, and the source management table for storing the record is stored in the storage unit 73. In S330, the information is registered with corresponding record of the table.

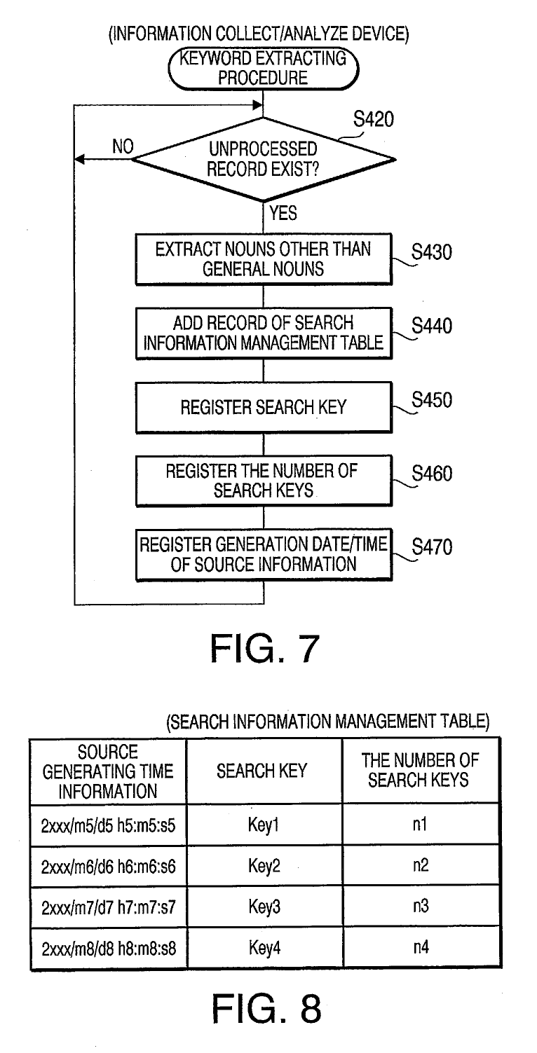

Next, a keyword extraction procedure which is repeatedly executed by an analyzing unit 81 after the information collect/analyze device 70 is started up, referring to a flowchart of FIG. 7.

When the keyword extraction procedure is started, the control judges whether an unprocessed record which is not subjected to be processed in the following steps is registered with the source management table described above (S420). If the unprocessed record is not registered (S420: NO), the control pauses until an unprocessed record is registered in the source information registration procedure by repeating S420.

If the control determines that there exists an unprocessed record (S420: YES), the control sets the unprocessed record as a target record, reads out the text data (i.e., the transmission target data) having a predetermined file name in the target record, analyzes the text data in accordance with a known morphological analysis to extracts nouns included in the text represented by the text data, and then extracts nouns other than predetermined ones as keywords (S430). Specifically, general nouns which are considered to be inappropriate as keywords for a purpose of searching for contents are identified as the predetermined nouns, and the predetermined nouns are excluded from the nouns extracted according to the morphological analysis to extract the keywords.

Next, the control adds as many records as the kinds of keywords extracted in S430 to the search information management table (S440). The search information management table is stored in the storage unit 73 as a data table for storing, as shown in FIG. 8, the source generation time information, search keys, the number of search keys, etc. In S440, the control adds new records necessary for setting the information above in the following steps, the number of added records being the same as the number of keywords.

Next, the keywords extracted in S430, and the number of the keywords are registered with items of the “search key” and the “number of the search keys” of the same record, respectively (S450 and S460). Next, in the item of “source generation time information” in each record, the time represented by the “source generation time information” of the corresponding record of the source management table is stored (S470). Then, the control returns to S420 and pauses until the unprocessed record is registered with the source information registration procedure.

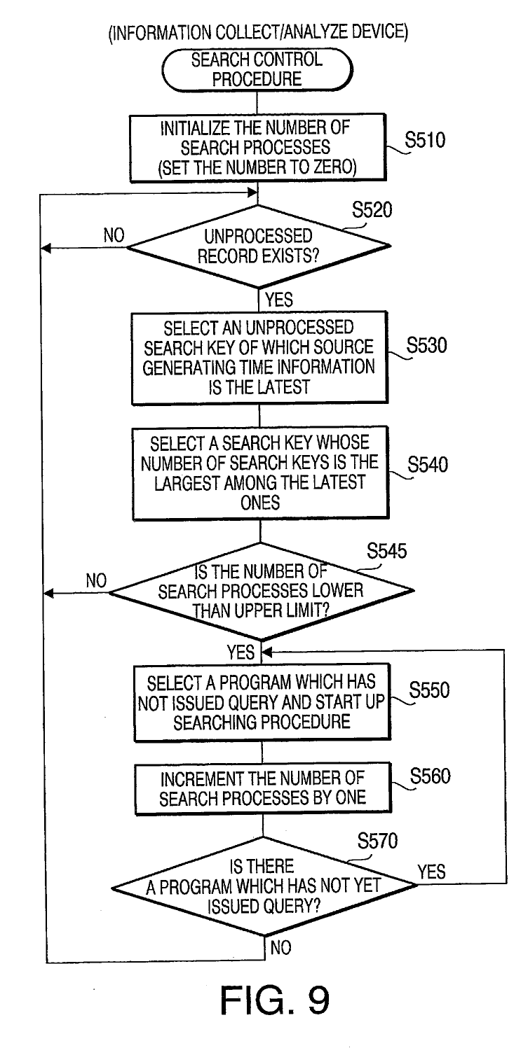

Next, a search control procedure which is repeatedly executed by the searching unit 83 after the information collect/analyze device 70 was started will be described with reference to FIG. 9.

When the search control procedure is started, the control initializes the number of search processes to zero (S510). Then, in S520, the control judges whether an unprocessed record which is not subjected to be processed in the following steps (S550-). If the control determines that the unprocessed record is not registered (S520: NO), the control pauses until an unprocessed record is registered in the above-described keyword extraction procedure by repeating S520.

If the control determines that the unprocessed record is registered with the search information management table (S520: YES), the control selects, from among the registered records, one having the latest time represented by the “source generation time information” (S530), and one having the largest number of the “search keys” as the target record (S540).

Next, the control judges whether the number of searching processes is less than a predetermined upper limit (which is 10 according to the illustrative embodiment) in S545. If the number of the searching processes is equal to or greater than the upper limit (S545: NO), the control returns to S520 and judges whether an unprocessed record is registered with the search information management table.

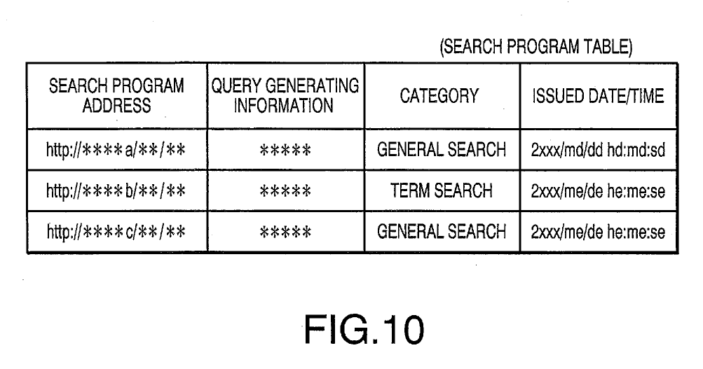

Next, the control selects a searching program which has not issued a query from among searching programs identified by the record of the searching program table, and executes a searching procedure that starts the selected searching program (S550). According to the first illustrative embodiment, as shown in FIG. 10, a searching program address representing address information of a server (the information searching server 20 in the first illustrative embodiment) containing the searching program, a query generating information representing a method of generating a query including a searching formula, category information representing a category of the contents searched by the searching program, and a searching program table which is a data table storing issued time of the query and the like are stored in the storage unit 73.

In S550, the control selects, from among the records registered with the searching program table described above, a record for which the query corresponding to the “searching key” of the target record selected in S530 and S540 has not been generated or transmitted, and starts up the searching procedure based on the selected record so that the searching program identified by the record is executed on the server side.

It should be noted that the above-described search information management table is a queue type data table, and the target record selected in S530 and S540 is deleted from the search information management table as a processed record when the searching procedure is started up in S550.

In S560, the control increments the number of searching processes by one, and judges whether there is a searching program which has not yet issued a query among the searching programs identified by the record of the searching program table (S570). Similarly in S550, the control determines that there exists a searching program that has not yet issued the query if there is a record for which generation and transmission of the query corresponding to the “search key” of the target record selected in S530 and S540 in the searching program table.

If the control determines that there exists a searching program that has not yet issued the query (S570: YES), the control returns to S550, and selects a searching program that has not issued the query to start up the searching procedure. If the control determines that there is no searching program that has not issued the query (S570: NO), the control returns to S520 and pauses until the unprocessed record is registered in the above-described keyword extraction procedure.

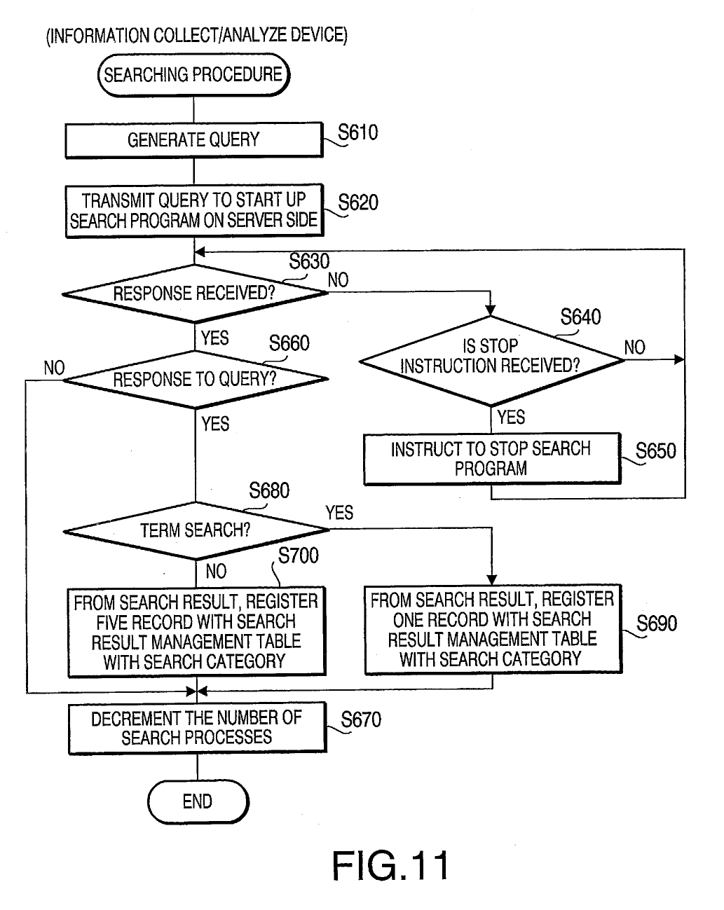

Next, the searching procedure started up in S550 of FIG. 9 will be described with reference to FIG. 11. The searching procedure is executed by the searching unit 83 in parallel with the search control procedure described above.

When the searching procedure is started, the control generates a searching formula based on the “search key” in the target record of the searching information table selected in S530 and S540 of FIG. 9 and the “query information” in the record selected from the search program table in S550 of FIG. 9, and generates a query containing the searching formula (S610).

Next, the control transmits the query generated in S610 to the “searching program address” contained in the record selected from the searching program table in S550 of FIG. 9, thereby starting up the searching program corresponding to the record on the server (which is the information searching server 20 in the illustrative embodiment) side (S620).

Upon receipt of the query, the server (e.g., the information searching server 20) searches for contents in accordance with the searching formula contained in the query. Then, the address of one or more content searched by the server is returned as a response to the query.

It should be noted that, according to the first illustrative embodiment, the response to the query returned by the server is configured such that an evaluation value indicating the evaluation of the content is associated with the address information. The evaluation value is a parameter representing the degree of importance of each content calculated in accordance with a predetermined method in the server.

After instructing the server to execute the searching program in S620, if there is no response from the server (S630: NO), the control judges whether a stop instruction to stop the searching procedure has been issued in accordance with the operation of the user or an external instruction (S640). If the stop instruction has not bee issued (S640: NO), the control returns to S630.

If the control determines that the stop instruction has been issued (S640: YES), the control transmits a stop command, in S640, to stop the searching program, which was started in S620 on the server side, to the server to which the query was transmitted in S620. Then, the control returns to S630. From the server that receives the stop command, information indicating that the searching program has been stopped is transmitted in response to the stop command.

As above, after the query is transmitted in S620 or the stop command is transmitted in S650, and if the response from the server is received (S630: YES), and the response is not the response to the query (i.e., if it is the response to the stop command) (S660: NO), the control decrements one from the number of searching processes (S670) and finishes the searching procedure.

If the response received from the server in S630 is the response to the query, that is, the search result of contents (S660: YES), the control checks the “category information” of the record selected from the searching program table in S550 of FIG. 9 (S680).

If the category information represents the “term search” (S680: YES), the control registers one piece of address information, from among one or more pieces of address information of contents received as the response from the server, with the search result management table (S690).

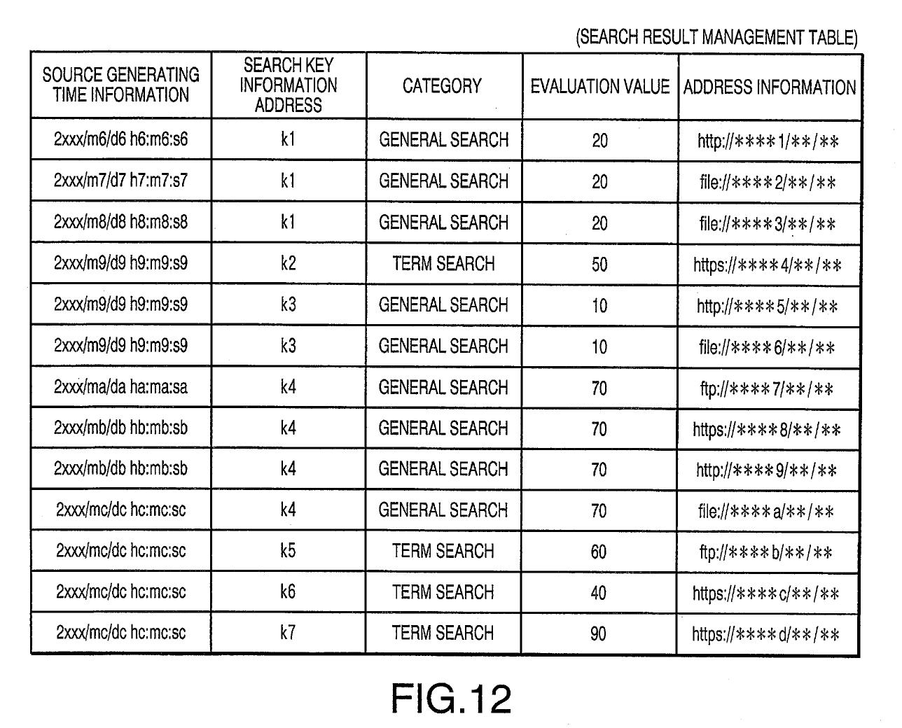

FIG. 12 shows an example of the search result management table, which stores source generation time information, search key information addresses, category information, evaluation values and address (URL) information in a related fashion. In S690, from among one or more pieces of the address information of the contents, which are response from the server, the piece of the address information of which the evaluation value has the highest value is registered with the same record of the search result management table. Specifically, the address information corresponding to the highest evaluation value is registered as the “address information”, the evaluation value is registered as the “evaluation value”, the information indicating the “term search” is registered as “category information”. Further, the stored portion of the target record of the search information management table selected in S530 and S540 is registered as a “search key information address”.

If the category information indicates the “general search” (S680: NO), from among the one or more pieces of address information of the contents received as a response from the server, a predetermined number of pieces of address information are registered with the search result management table (S700). It should be noted that, according to the first illustrative embodiment, at most five pieces of address information are registered. If the actual number of the pieces of the address information is less than five, the actual number of pieces of the address information are registered.

Specifically, from among the one or more pieces of address information received as a response from the server, for example, information related to at most five pieces of address information having higher evaluation values than the others are registered with the corresponding records of the search result management table in the descending order of the evaluation values, respectively.

More specifically, five pieces of address information of top five evaluation values are registered as “address information” of different records, and the evaluation values corresponding to the five pieces of address information are registered as the evaluation values for the five records. Further, information indicating the general search is registered with the “category information” of each of the five records, and the stored portions of the target record in the search information management table selected in S530 and S540 of FIG. 9 are registered as “search key information address”.

After the registration of various pieces of information with the search result management table in S690 or S700, the control proceeds to S670 and decrements one from the number of searching processes. Then, the control finishes the searching procedure.

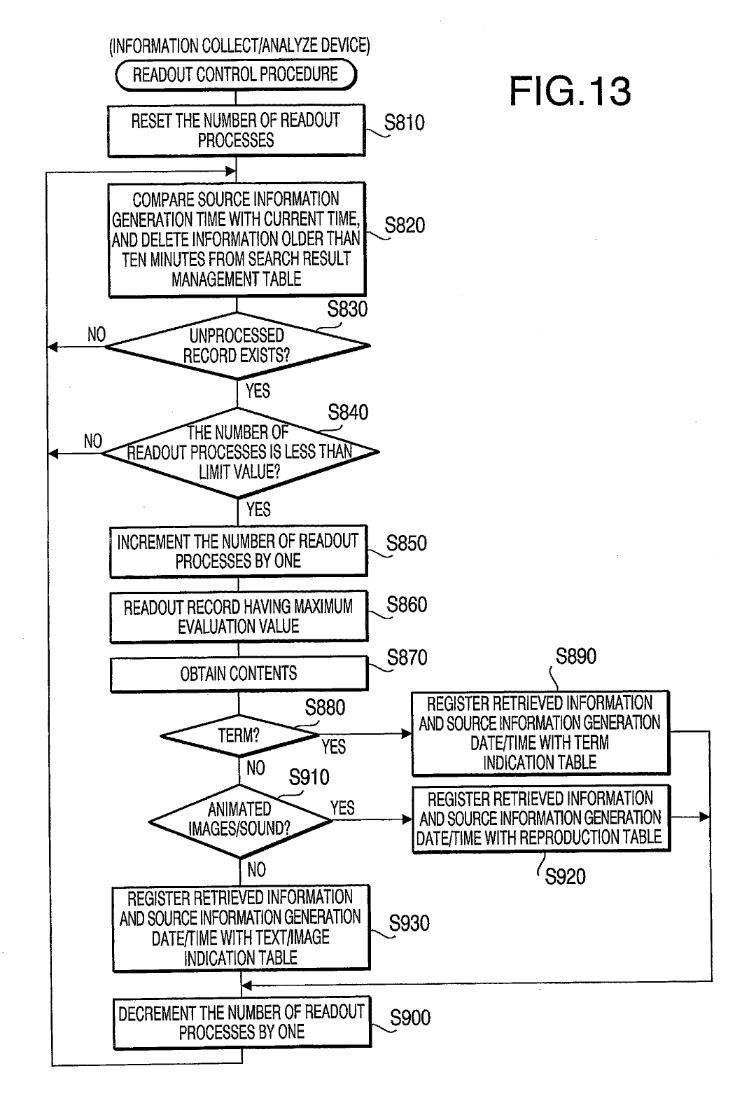

Next, a readout control procedure repeatedly executed by the reading unit 85 after the information collect/analyze device 70 was started, with reference to FIG. 13.

When the readout control procedure is started, the control resets the number of readout processes (i.e., set to zero) in S810. Then, the control deletes records of which the time represented by the “source generation time information” is prior to the current time by a predetermined amount (ten minutes, according to the first illustrative embodiment) from the search result management table (S820).

Next, the control judges whether there exists an unprocessed record which is not subjected to be processed in the following processes (S830). If the control determines that there is no unprocessed record in the search result management table (S830: NO), the control returns to S820. If the control determines that there exists an unprocessed record (S830: YES), the control judges whether the number of the readout processes is less than a predetermined upper limit value (which is ten, according to the first illustrative embodiment) (S840). If the number of the readout processes is equal to or greater than the upper limit (S840: NO), the control returns to S820.

If the number of readout processes is less than the upper limit (S840: YES), the control increments the number of the readout processes by one (S850). Then, the control extracts, from among the unprocessed records in the search result management table, a record of which the “evaluation value” has the largest value (S860), and from the server (the information search server 20, according to the illustrative embodiment) whose location is indicated by the “address information” of the thus extracted record, the contents are obtained (S870). Specifically, in this case, a session between the server (whose location is indicated by the “address information”) is established (i.e., the communication is started), a request (e.g., HTTP request) for contents is transmitted to the server, and the contents which is transmitted by the server in response to the request (e.g., by the HTTP response) are received.

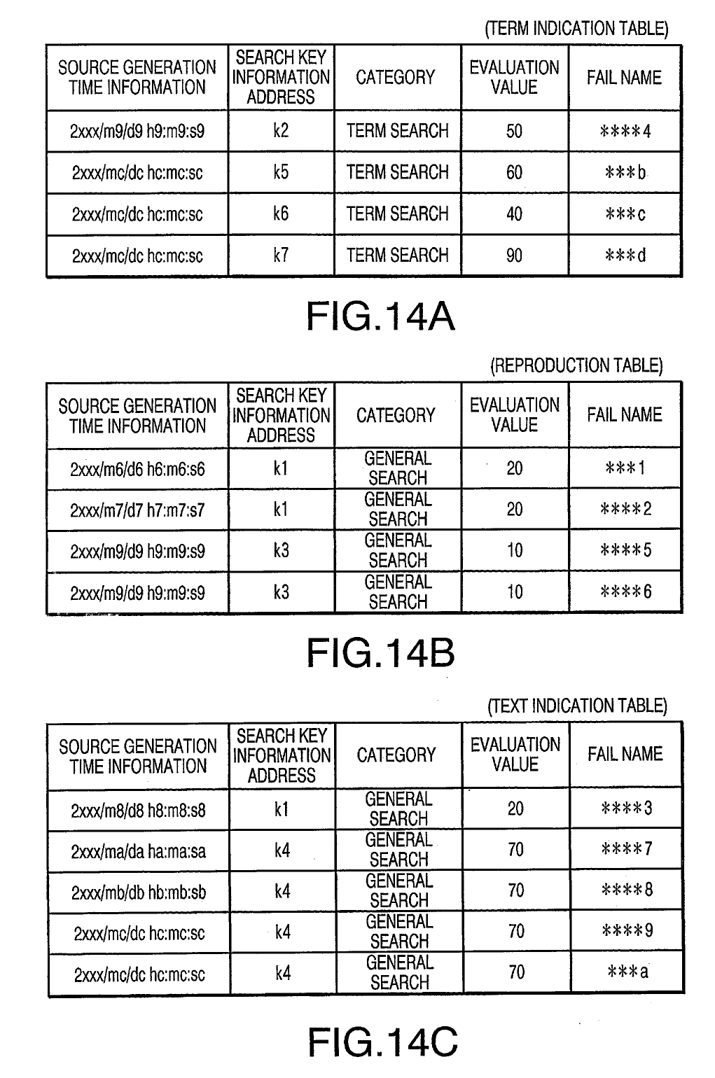

Next, in S880, the control checks the type of the contents obtained in S870. If the contents are represented by data (text data) indicating terms and the like (S880: YES), the control stores the data in the storage unit 73 with assigning a predetermined file name. Further, the control registers the file name (or the path name) with a term indication table in association with the “source generation time information”, “search key information”, “category information” and “evaluation value” (S890). Thereafter, the control reduces one from the number of the readout processes (S900), and returns to S820. The term indication table is, as shown in FIG. 14A, a data table for registering a record composed of the “source generation time information”, “search key information”, “category information”, “evaluation value” and “file name”. In S890, the control registers the read out information and the source information generation date/time with the corresponding record of the term indication table.

If the contents are composed of data representing animated images and/or sounds (i.e., image data, sound data) (S880: NO; S910: YES), the control assigns a predetermined file name and stores the same in the storage unit 73. Further, in S920, the control registers the file name (or path name) with a reproduction table in association with the “source generation time information”, “search key information”, “category information” and “evaluation value” of the record extracted in S860. Thereafter, the control proceeds to S900, decrements the number of readout processes by one, and returns to S820. The reproduction table is, similar to the term indication table, a data table for registering records each includes the “source generation time information”, “search key information”, “category information”, “evaluation value” and “file name” (see FIG. 14B). In S920, the control registers the read out information and the source information generation date/time with the corresponding record of the reproduction table.

If the contents are composed of data representing information other than the terms (i.e., the text data, image data) (S910: NO), the control assigns a predetermined file name to the data and stores the same in the storage unit 73. The control further registers the file name (or path name) with a text/image indication table (S930) in association with the “source generation time information”, “search key information”, “category information” and “evaluation value” of the record extracted in S860. Then, the control decrements one from the number of readout processes by one, and returns to S820. It should be noted that the text/image indication table is, similar to the term indication table, a data table for registering records each includes the “source generation time information”, “search key information”, “category information”, “evaluation value” and “file name” (see FIG. 14C). In S930, the control registers the read out information and the source information generation date/time with the corresponding record of the text/image indication table.

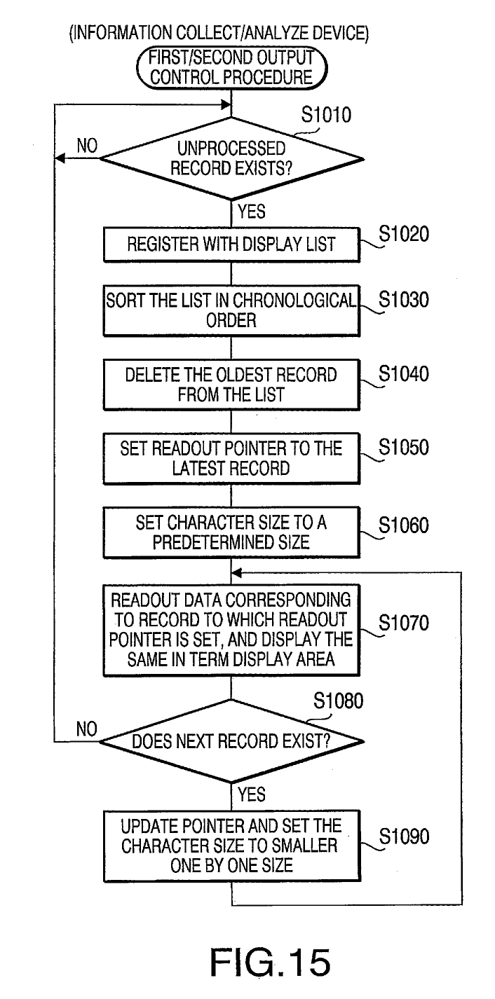

Next, a first output control procedure which is repeatedly executed by the output control unit 87 after the information collect/analyze unit 70 was started up will be described with reference to a flowchart shown in FIG. 15.

When the first output control procedure is started, firstly, the control pauses until an unprocessed record which is not subjected to be processed in the following steps are registered with the term indication table in accordance with the readout control procedure described above. That is, the control pauses while decision at S1010 is NO.

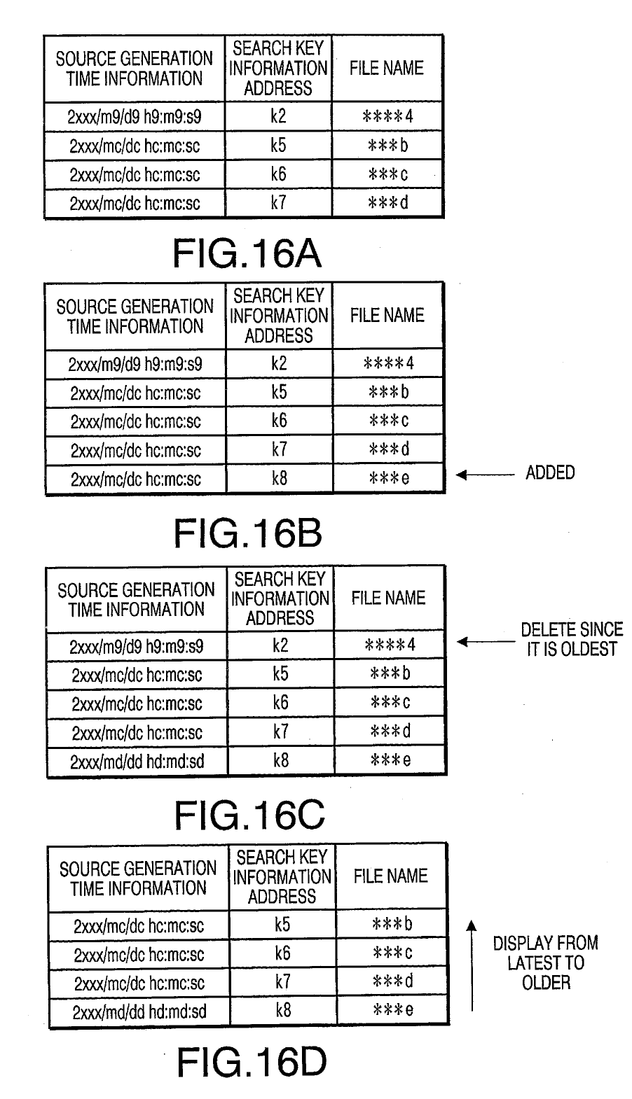

When the unprocessed record is registered (S1010: YES), the control registers the “source generation time information”, “search key information” and “file name” of the record with a term indication list (S1020). The term indication list is a data table for registering records each having the “source generation time information”, “search key information”, and “file name”, as shown in FIG. 16A. In S1020, the information is registered with the corresponding record of the table (see FIG. 16B).

Next, the control sorts the records in the term indication list in the ascending order of the “source generation time information” (S1030). Then, the term indication list shows the records such that older records (i.e., the records of which the “source generation time information” represents older time) at upper portion (see FIG. 16C).

In S1040, the control deletes a record of which the time represented by the “source generation time information” is the oldest (i.e., the record arranged at the uppermost position in the list) from among the record registered with the term indication list (see FIG. 16C).

Then, the control sets a reading pointer for designating a record to be read out from the term indication list in the following process to a record having the “source generation time information” indicating the latest time (i.e., the record located at the lowermost position of the list at this stage) in S1050.

In S1060, the control sets the size of the letters/characters when the text represented by the data having the “file name” indicated in the record that is designated by the reading pointer to a predetermined size (e.g., the maximum size). Then, the control reads out the data indicated by the “file name” of the record to which the reading pointer is set at this stage. The text represented by the thus read data is displayed in the term display area (see FIG. 2) of the contents providing window of the display unit 77 with the letter/character size as set (S1070). The text may be scrolled from the lower portion to the upper portion within the term display area.

Next, the control judges whether there is a record of which the time represented by the “source generation time information” is the latest except for the record to which the reading pointer is set (i.e., the control judges whether all the records have been read) in S1080. If such a record exists (S1080: YES), the control sets the reading pointer to the record, and sets the letter/character size of the text represented by the data of the “file name” of the record to a smaller size (S1090). Then, the control returns to S1070, and displays the text represented by the data having the “file name” of the record. It should be noted that, in 1070, the text is arranged to be displayed below the previously displayed text which is being scrolled, and the newly added text is also scrolled in association with the scroll of the previously displayed text.

If a next record does not exit (S1080: NO), the control returns to S1010 and pauses until a unprocessed record is registered.

Next, a second output control procedure repeatedly executed by the output control unit 87 after the information collect/analyze device 70 was started up will be executed in parallel with the first output control procedure described. It should be noted that the second output control procedure is similar to the first output control procedure if the “term indication table”, “term indication list” and the “term display area” of the first control procedure are replaced by the “text/image indication table”, “text/image indication list” and “text/image display area”, respectively. Accordingly, description of the second output control procedure will be omitted for the brevity.

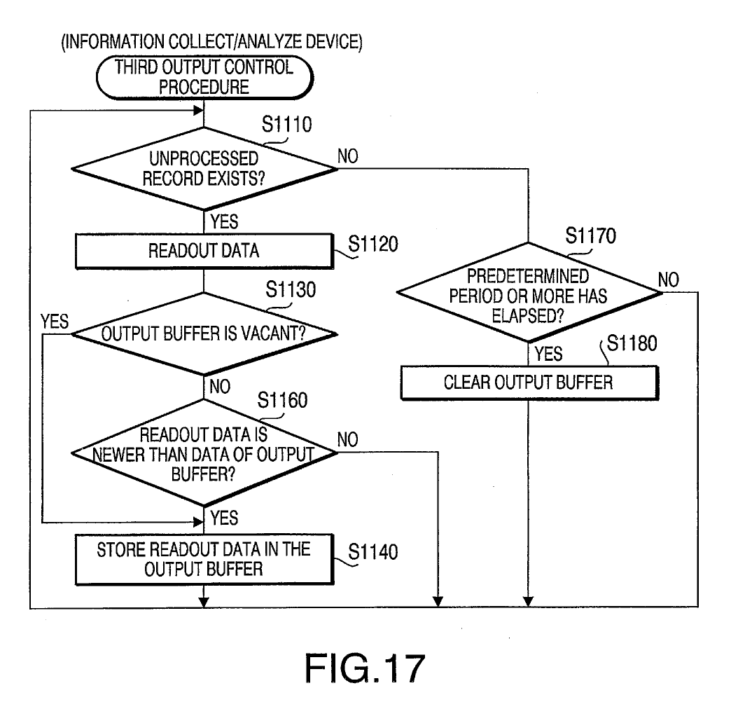

A third output control procedure repeatedly executed by the output control unit 87 after the information collect/analyze device 70 was started up will be described with reference to a flowchart shown in FIG. 17. The third output control procedure is executed by the output control unit 87 in parallel with the above-described first and second output control procedures.

When the third output control procedure is started, the control judges whether an unprocessed record is registered with the reproduction table in the readout control procedure (S1110). If the unprocessed record is remain registered (S1110: YES), the control reads out the data (animated image data and sound data) whose “file name” is indicated in the record (S1120).

Then, the control judges whether an output buffer is vacant (S1130). The output buffer is used for reproducing animated image in the animated image reproducing area on the contents providing window displayed on the display unit 77, and for outputting sound wave from the sound output unit 79. If the buffer is vacant (S1130: YES), the control writes the data read out in S1120 in the output buffer to start reproducing/outputting the data (S1140). Then, the control returns to S1110. With S1140, if the data retrieved in S1120 is the animated image data, reproduction of the animated image in the animated image reproduction area and the sound output from the sound output unit 79 are started. If the retrieved data is the sound data, sound output from the sound output unit 79 is started.

When the output buffer is vacant (S1130: NO), if the data written in the output buffer at this stage is newer than the data retrieved in S1120 (S1160: YES), the control proceeds to S1140. In S1140, the control overwrites the output buffer with the retrieved data, thereby terminating the reproduction of the sound data which is being output. After the data is overwritten, the control starts reproduction of the data and returns to S1110. If the data written in the output buffer is not newer than the retrieved data (S1160: NO), the control returns to S1110 without executing S1140. It should be noted that the comparison of the data in S1160 is executed by comparing the time represented by the “source generation time information” of the record registered in S1110 with the time represented by the “source generation time information” of the record in the reproduction table corresponding to the “file name” of the data stored in the output buffer. It should be noted that the reproduction of the sound by overwriting the output buffer in S1140 may be modified such that the reproduction of the data previously stored in the output buffer.

If an unprocessed record is not registered with the reproduction table (S1110: NO), the control judges whether the time represented by the “source generation time information” of the record in the reproduction table corresponding to the “fine name” of the data stored in the output buffer indicates time later than the “current time” by a predetermined period (which is ten minutes, according to the illustrative embodiment) (S1170). If the “current time” is predetermined period has elapsed with respect to the current time (S1170: NO), the control returns to S1110.

If the time represented by the “source generation time information” of the record indicates a time elapsed from the “current time” by the predetermined period (S1170: YES), the control clears the output buffer (S1180), and returns to S1110.

As above, according to the system 1 described above, the information collect/analyze device 70 can collect:

text data representing the text which is subsequently updated in accordance with the input operation through the input unit 41 of the PC 30;

text data representing the text to be displayed on the display unit 43 in accordance with the input operation through the input unit 41 of the PC 30; and

text data converted from sound data input/output through the sound input unit 61 and sound output unit 63 of the telephone device 50 are collected (S180 of FIG. 3, S260 of FIG. 4 and S310-S330 of FIG. 5).

From the thus collected text data, the control extracts keywords (S430, S450 of FIG. 7) which are used as search keys when contents are searched. The information collect/analyze device 70 transmits query that is generated based on the thus obtained search keys to the server (i.e., information searching server 20) to start up the search program on the server side to search for the contents (S620 of FIG. 11). Thereafter, the information collect/analyze device 70 collects the contents (S690 and S700 of FIG. 11) as it receives the contents searched on the server side.

The contents are displayed and/or reproduced (S1070 of FIG. 15, S1140 of FIG. 17) through the contents providing screen displayed on the display unit 77.

Specifically, the contents composed of the text of terms are registered with the term indication table in the output control procedure executed by the output control unit 87 (S890 of FIG. 13). Then, in the first output control procedure, the contents are sorted based on the time represented by the “source generation time information”, that is, the time when the text data, based on which the search key is generated, is generated (S170 of FIG. 3, S250 of FIG. 4) on the PC 30 or the telephone device 50 in the ascending (or descending) order. Then, the sorted contents are sequentially displayed on the contents providing window from the latest one to older one (S1050-S1090 of FIG. 15).

The contents composed of information other than terms are also registered with the text/image table in the output control procedure executed by the output control unit 87 (S930 of FIG. 13). Then, in the second output control procedure, the contents are sorted based on the time represented by the “source generation time information”, that is, the time when the contents were obtained in the ascending (or descending) order. Then, the sorted contents are sequentially displayed on the contents providing window from the latest one to older one (S1050-S1070 of FIG. 15).

The contents composed of the animated image and sound are also registered with the reproduction table (S920 of FIG. 13). Then, in the third output control procedure, the contents are sorted based on the time represented by the “source generation time information”, that is, the time when the contents were obtained in the ascending (or descending) order. Then, the sorted contents are sequentially reproduced through the contents providing window from the latest one to older one (S1150-S1140 of FIG. 16).

As above, by displaying, reproducing data through the display unit 77 and/or by outputting sound through the sound output unit 79, the contents can be provided to the user.

As above, the contents searched based on the searching keys extracted from the text data which was generated later is assumed to meet the user's interest since the interval between input of the text and generation of the search key is relatively short.

Therefore, by displaying and/or reproducing such contents prior to the other, it becomes possible to reduce the interval between the input/output of the text from which the search keys are extracted and display and/or reproduction of the contents. As a result, the contents the user may be interested in can be provided at an appropriate timing.

According to the first and second output control procedures, the contents are displayed such that ones corresponding to the times represented by the “source generation time information” are later are displayed in larger sizes. In particular, the latest content is displayed differently from the other contents (see S1060, S1070 of FIG. 15). That is, the latest content is displayed prior to the other contents. Therefore, the content which the user may be most interested in can be provided to the user prior to the other contents.

Further, in the first and second output control procedures, the records of the display list are sorted in accordance with the times represented by the “source generation time information”. Then, according to the sorted list, the contents are arranged in the contents providing window such that the latest one is located at the top and earlier ones are arranged below (S1050-S1090 of FIG. 15). Since the later contents are displayed in an upper portion, the contents the user may be interested in are displayed in the upper portion of the list. With this configuration, the order of the records make it possible to provide the later contents to the user prior to the older ones.

In the information collect/analyze device 70, the contents are collected based on the searching keys which are keywords extracted from the text data collected from the PC 30 and the telephone device 50 (S430 of FIG. 7, S610 and S620 of FIG. 11). Since the searching keys (i.e., keywords) are extracted from the text represented by the text data, and the searching is executed using the thus extracted searching keys, unnecessary texts can be excluded when the searching is executed. Therefore, the contents that meet the user's intention can be well searched.

It should be noted that the above-described first illustrative embodiment can be modified in various ways according to aspects of the invention.

In the first illustrative embodiment, the first and second output control procedures (FIGS. 15 and 17) are executed by the output control unit 87 of the information collect/analyze device 70. This configuration may be modified such that the first and/or second output control procedures are executed by the control unit 71 of the information collect/analyze device 70 in parallel with the other procedures.

In the first illustrative embodiment, in the first and second output control procedures, the contents are displayed such that the latest one is displayed in the largest size, while the older contents are displayed in smaller sizes based on the times represented by the “source generation time information”. With this configuration, the latest content is displayed to have a priority as it is displayed to have the largest size (S1070-S1090). This configuration is an exemplary one, and any other method to indicate the priority may be employed. For example, it may be possible to modify the first and second output control procedures such that only the contents of which the times represented by the “source generation time information” are the latest. In such a case, after execution of S1070 of FIG. 15, S1080 is skipped and the control may be returned to S1010.

In the above-described illustrative embodiment, the contents are provided to the user by display the same on the display unit 77 and/or by outputting the sound through the sound output unit 79.

Further, in the first illustrative embodiment, the PC 30, the telephone device 50 and the information collect/analyze device 70 are different devices. It is of course possible that the PC 30 or the telephone device 50 is integrated with the information collect/analyze device 70.

In the first illustrative embodiment, the contents to be displayed/reproduced prior to the others are determined based on the time when the text data (transmission target data) from which the search key is extracted on the PC 30 or the telephone device 50 side (see S1050 of FIG. 15, S1160 of FIG. 17). It is possible to use different time (i.e., the time other than the data generation time) for determining the priority in displaying/reproducing.

For example, the time when the contents were obtained in S870 (FIG. 13) may be referred to when the priority is determined. In such a case, the procedure may be modified such that the current time may be registered as the “source generation time information” in S890, S920 and S930 of FIG. 13. Alternatively, the time when the query is generated or transmitted in S610 or S620 of FIG. 11. In this case, the time represented by the “source generation time information” is updated in accordance with the current time.

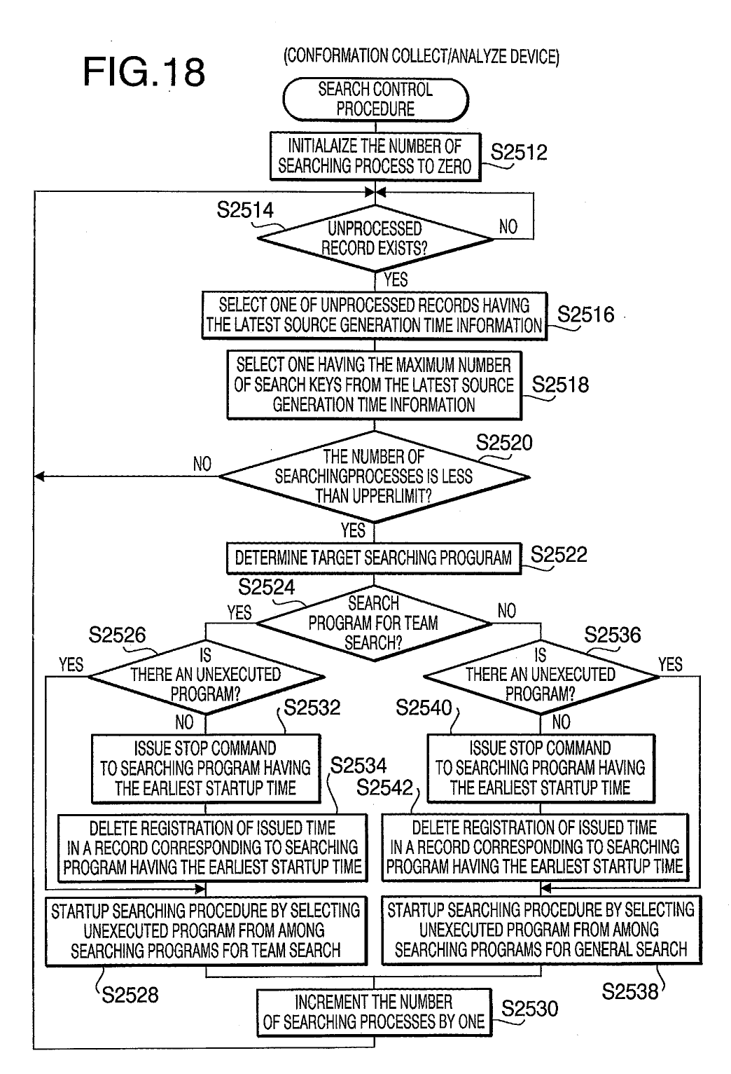

Next, the detection control procedure according to a second embodiment will be described with reference to FIG. 18. It should be noted that the system configuration of the second embodiment is the same as that of the first embodiment shown in FIG. 1. Further, the PC investigating procedure, the telephone investigating procedure and the keyword extracting procedure according to the second embodiment are same as those of the first embodiment respectively shown in FIGS. 3, 4 and 7.

When the search control procedure is started, the control initializes the number of searching processes (i.e., set the number to zero) in S2512 (FIG. 18). Next, the control judges whether an unprocessed record remains registered with the search information management table (S2514). If the control determines that no unprocessed record is registered (S2514), the control pauses until an unprocessed record (i.e., repeats S2514).

If the control determines that the unprocessed record is registered with the search information management table (S2514: YES), the control selects a registered record having the latest time represented by the “source generation time information” (S2516) and the number of the search keys is the maximum (S2518) as the process target record.

Next, the control judges whether the number of the searching processes is less than the predetermined upper limit (which is 10 according to the embodiment) in S2520. If the number of the search processes is equal to or greater than the upper limit (S2520: NO), the control returns to S2514, and pauses until the unprocessed record is registered in the keyword extracting procedure.

In S2520, if the control determines that the number of the searching processes is less than the upper limit (S2520: YES), the control determines the searching program to be executed in the following steps in S2522 based on the “number of searching keys” in the process target record of the search information management table selected in S2516 and S2518, and executes the searching procedure based on the type of the searching program.

It should be noted that the above-described search information management table is a queue matrix type table, and with respect to the target records selected in S2516 and S2518, when the searching procedure is executed, they are deleted from the searching information table as the processed records.

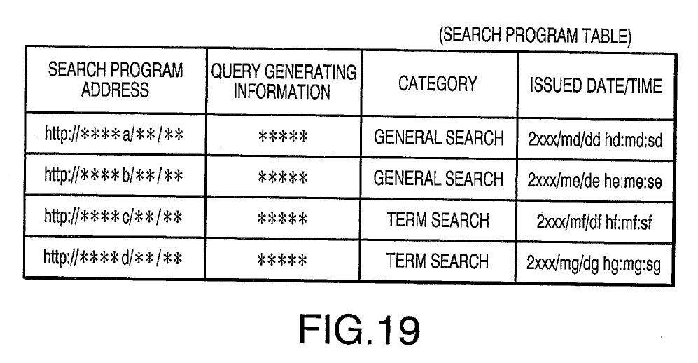

In the second illustrative embodiment, as shown in FIG. 19, the search program table is stored in storage unit 73. Specifically, the search program table stores a search program address indicating the address information of a server that contains the search program, query generation information indicating a method of generating the query including a search formula, a category information indicating a category of a content to be searched by the search program, and

a time (date and time) when the query was issued.

In search program table, the “category information” represents the type of the search program. In the second illustrative invention, there are two types of search programs: one for “term search” program; and one for “general search”. In S2522, if the “number of the search keys in the process target record of the search information management table is less than a predetermined number (which is five according to the second illustrative embodiment), the search program for the term search is selected, while if the number of the search keys is equal to or more than the predetermined number, a search program file for the general search is selected. It should be noted that, in the second illustrative embodiment, a method of determining the search program determines the search program in accordance with the number of search keys. However, any other method may be employed.

If the searching program determined in S2522 is for the “term search” (S2524: YES), the control judges whether there is a “term search” program which corresponds to the record of the searching program table and is not executed currently (S2526).

In the second illustrative embodiment, the “issued time” included in the record registered with the searching program table stores the time when the searching program corresponding the record is started, and when the searching program is finished, the registered items are deleted.

That is, among the searching programs corresponding to the records registered with the searching program table, one for which the time information is stored in the “issued time” is the searching program currently executed, and one for which no information is stored in the “issued time” is the searching program which is not being executed.

For each of the “term search” searching programs sand “general search” searching programs, conditions of parallel execution of the programs are determined. In S2526, based on the registration status of the “issued time” of each record registered with the searching program table, the control judges whether there are searching programs for the “term search” currently unexecuted.

If there exist searching programs for the “general search” that are not executed (S2526: YES), the control selects one of such programs, and a search process (described later) for starting up the searching program (S2528). The control then increments the number of search processes by one (S2530), and returns to S2512, where pauses until an unprocessed record is registered in the keyword extracting procedure described above.

If there is no unexecuted program (S2526: NO), the control issues a stop command to the searching program which was started at the earliest time among the searching programs of “term search” corresponding to the record of the searching program table (S2532). In this step, the stop command is issued to the searching program of which the startup time represented by the “issued time” is the oldest (i.e., the program having been executed for the longest period), among the “term search” searching programs corresponding to the record of the search program table. With the stop command, via the searching process started up in S2528, the termination of the searching program is instructed to the server.

After the registered content of the “issued time” of the record corresponding to the searching program having the earliest startup time is deleted (S2534), the control proceeds to S2528 and selects the searching program corresponding to the record whose content was deleted, and starts up the searching procedure for executing the selected searching program.

If the searching program determined in S2522 is the “general search” program (S2524: NO), the control judges, in S2536, whether there are unexecuted “general search” searching programs from among the searching programs corresponding to the records of the searching program table as in the process of S2526.

If there are unexecuted “general search” searching programs (S2536: YES), the control selects one of them, starts up the searching procedure for starting up the searching program (S2538). In S2580, the control increments the number of the searching processes by one, and returns to S2514, where pauses until an unprocessed record is registered in the keyword extraction procedure.

If there is no unexecuted program (S2536: NO), as in S2532, from among the “general search” searching programs corresponding to the records of the searching program table, one having the earliest startup time is selected and the stop command is issued therefor (S2540). By the stop command, via the searching procedure started in S2538, the command to stop the searching program is transmitted to the server.

After deleting the registered content of the “issued time” of the record corresponding to the searching program having the oldest startup time (S2542), the control proceeds to S2538, and selects the searching program corresponding to the record of which the registered content was deleted and starts the searching procedure for stating the searching program.

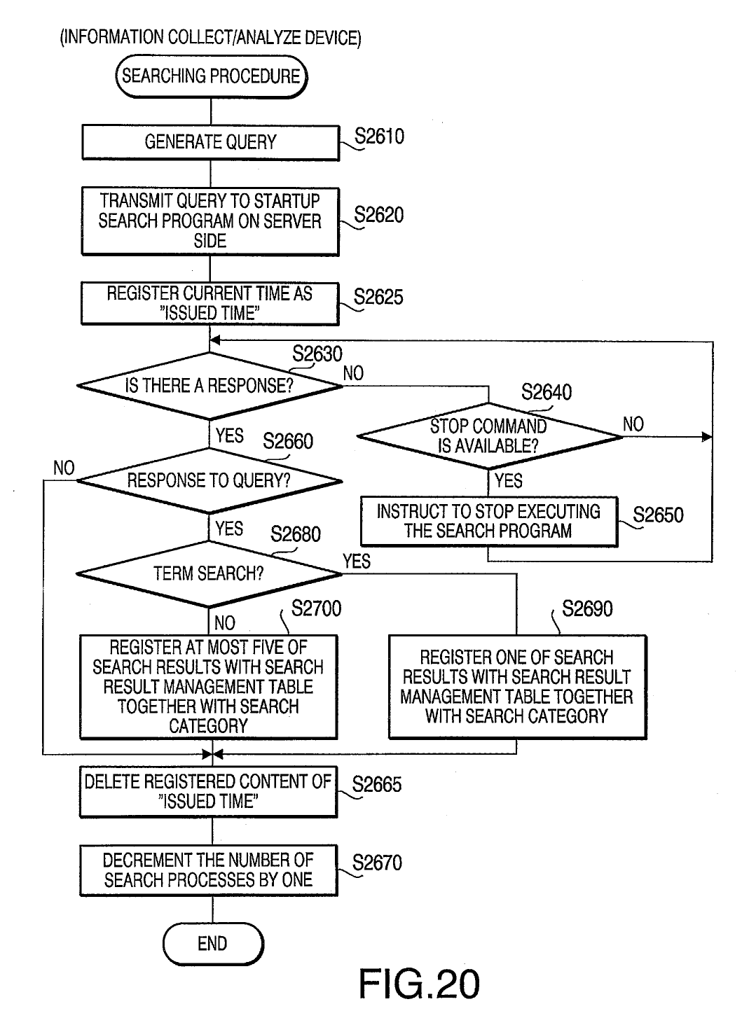

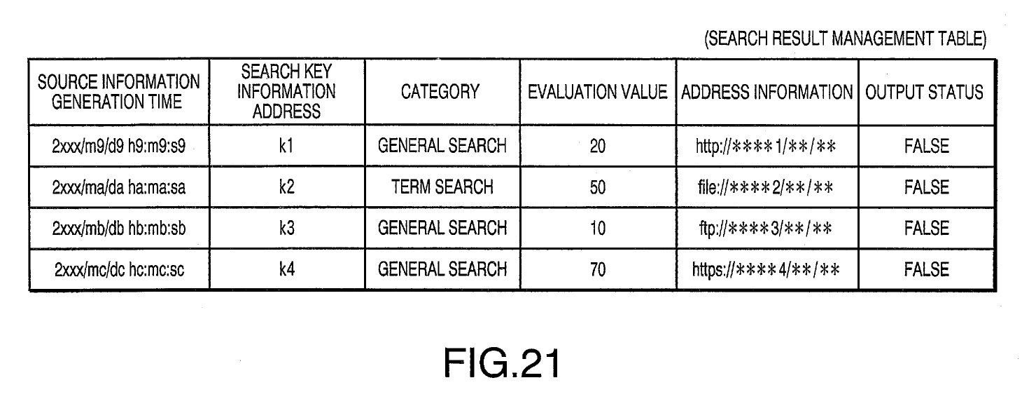

Next, the searching procedure executed in S2528, S2838 of FIG. 18 will be described with reference to FIG. 20. It should be noted that the searching procedure is executed by the searching unit 83 in parallel with the searching control procedure described above.

When the searching procedure is started, the control generates a searching formula based on the “search key” in the target record of the searching information table selected in S2516 and S2518 of FIG. 18 and the “query information” in the record selected from the search program table in S2528, S2538 of FIG. 18, and generates a query containing the searching formula (S2610).

Next, the control transmits the query generated in S2610 to the “searching program address” contained in the record selected from the searching program table in S2528, S2538 of FIG. 18, thereby starting up the searching program corresponding to the record on the server (which is the information searching server 20 in the illustrative embodiment) side (S2620).

Upon receipt of the query, the server (e.g., the information searching server 20) searches for contents in accordance with the searching formula contained in the query. Then, the address of one or more content searched by the server is returned as a response to the query.

It should be noted that, according to the first illustrative embodiment, the response to the query returned by the server is configured such that an evaluation value indicating the evaluation of the content is associated with the address information. The evaluation value is a parameter representing the degree of importance of each content calculated in accordance with a predetermined method in the server.

Next, the control registers the current time with the “issued time” of the record corresponding to the searching program started in S2620 in S2625.

After instructing the server to execute the searching program in S620, if there is no response from the server (S2630: NO), the control judges whether a stop instruction to stop the searching procedure has been issued in S2532 or S2540 of FIG. 18 (S2640). If the stop instruction has not bee issued (S2640: NO), the control returns to S2630.

If the control determines that the stop instruction has been issued (S2640: YES), the control transmits a stop command, in S2640, to stop the searching program, which was started in S2620 on the server side, to the server to which the query was transmitted in S2620. Then, the control returns to S2630. From the server that receives the stop command, information indicating that the searching program has been stopped is transmitted in response to the stop command.

As above, after the query is transmitted in S2620 or the stop command is transmitted in S2650, and if the response from the server is received (S2630: YES), and the response is not the response to the query (i.e., if it is the response to the stop command) (S2660: NO), the control deletes the “issued time” of the record of the search program table registered in S2625 (S2665). Then, the control decrements the number of search processes by one (S2670) and finishes the searching procedure.

If the response received from the server in S2630 is the response to the query, that is, the search result of contents (S2660: YES), the control checks the “category information” of the record selected from the searching program table in S2528 or S2538 of FIG. 18 (S2680).

If the category information represents the “term search” (S2680: YES), the control registers one piece of address information, from among one or more pieces of address information of contents received as the response from the server, with the search result management table (S2690).

FIG. 12 shows an example of the search result management table, which stores source generation time information, search key information addresses, category information, evaluation values, address (URL) information and output set information in a related fashion. In S2690, from among one or more pieces of the address information of the contents, which are response from the server, the piece of the address information of which the evaluation value has the highest value is registered with the same record of the search result management table. Specifically, the address information corresponding to the highest evaluation value is registered as the “address information”, the evaluation value is registered as the “evaluation value”, the information indicating the “term search” is registered as “category information”. It should be noted that the “output set information” is set to “FALSE” as the initial value.

If the category information indicates the “general search” (S2680: NO), from among the one or more pieces of address information of the contents received as a response from the server, a predetermined number of pieces of address information are registered with the search result management table (S2700). It should be noted that, according to the second illustrative embodiment, at most five pieces of address information are registered. If the actual number of the pieces of the address information is less than five, the actual number of pieces of the address information are registered. Also in S2700, the “output set information” is set to the initial value of “FALSE”.

After the registration of various pieces of information with the search result management table in S2690 or S2700, the control proceeds to S2665 or S2670 and finishes the searching procedure.

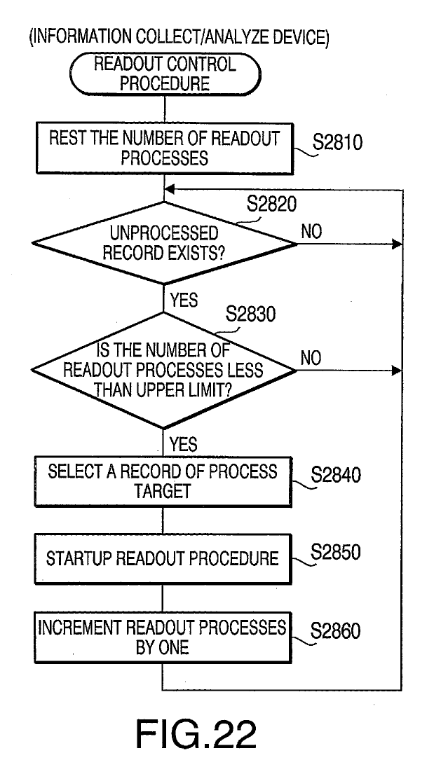

Next, a readout control procedure repeatedly executed by the readout unit 85 after the information collect/analyze device 70 was started with reference to FIG. 22.

When the readout control procedure is started, the control resets the number of readout processes (i.e., set to zero) in S2810.

Then, the control judges whether there is unprocessed record in the search result management table (S2820). If no unprocessed record exists (S2820: NO), the control pauses until an unprocessed record is registered in the search procedure. If there exists an unprocessed record (S2820: YES), the control judges whether the number of readout processes is less than a predetermined upper limit (which is 10 in the second embodiment) in S2830. If the number of readout processes is equal to or greater than the upper limit (S2830: NO), the control returns to S2820.

If the number of readout processes is less than the upper limit (S2830: YES), the control selects, among the unprocessed records of the search result management table, the latest one as the process target record (S2840), and based on the information of the record, the readout procedure (described later) is executed (S2850). Then, the control increments the number of readout processes by one (S2860) and returns to S2820.

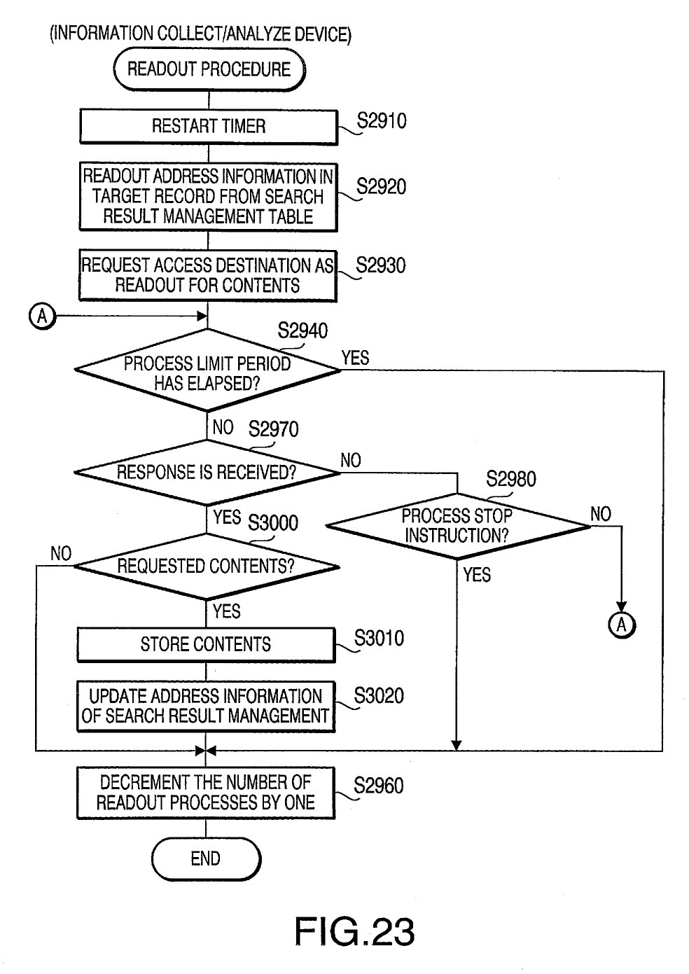

The readout procedure executed in S2850 of FIG. 22 will be described with reference to a flowchart shown in FIG. 23. The readout procedure is executed by the readout unit 85 in parallel with the readout control procedure described above.

When the readout procedure is started, the control resets the timer to restart counting (S2910).

Then, the control reads out the “address information” of the record selected in S2840 of FIG. 22, and request the access destination designated by the “address information” to transmit contents (S2930). If a device at the access destination which receives the request can provide the requested contents, it transmits the contents. If not, the access destination transmits error information.

After requesting for the contents, the control judges whether the count value of the timer exceeds a process limit time period (S2940). If the counted value exceeds the process limit time period (S2940: YES), the control decrements the number of readout process by one (S2960), and finishes the readout procedure.

If the control determines that the timer count value does not exceeds the process limit time period (S2940: NO), the control judges whether a response from the server that issued the request for the contents (S2070). If the response is not received (S2970: NO), the control proceeds to S2980. If the stop command to stop the readout procedure has not been issued based on the operation of the user of external command (S2980: NO), the control returns to S940. If the stop command has been issued (S2980: YES), the control proceeds to S2960 and decrements the number of the readout processes by one, and finishes the readout procedure.

If the control determines that the response from the server has been received (S2970: YES), the control proceeds to S3000. If the response is not the contents requested in S2930, that is, if the response is the error information (S3000: NO), the control proceeds to S2960, decrements the number of readout processes by one, and finishes the readout procedure. If the received response includes the contents requested in S2930 (S3000: YES), the control assigns a predetermined file name and stores the contents in the storage unit 73 (S3010). Then, the control updates the “address information” of the process target record selected in S2840 of FIG. 22 to the file name and path name of the stored location of the contents (S3020). Then, the control proceeds to S2960, decrements the number of processes by one, and finishes the readout process.

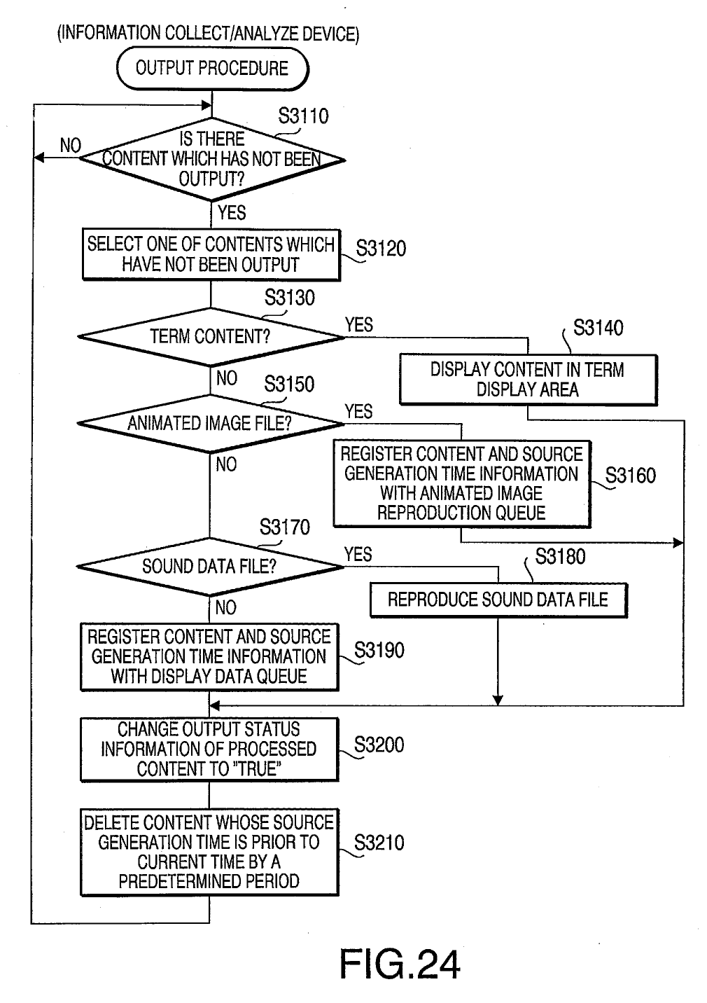

Next, the output procedure repeatedly executed by the output control unit 87 after the information collect/analyze device 70 was started will be described with reference to a flowchart shown in FIG. 24.

When the output procedure is started, firstly, the process judges whether there are contents which have not yet been output among the contents stored in the storage unit 73 in the readout procedure (S3110). If the control determines that there are no contents which have not been output (S3110: NO), the control pauses until the contents which have not yet been output are stored in the storage unit 73 in the readout procedure. It should be noted that whether the stored contents have been output or not is made based on the “address information” and “output set information” included in each record registered with the search result management table. Specifically, based on the “address information”, the existence of the contents at the path indicated therein is recognized, and if the “output set information” is set to the initial value (i.e., “FALSE”), the control determines that the contents have not yet been output.

If the control determines that there are contents which have not yet been output (S3110: YES), the control selects one of the contents as a process target content (S3120). Then, the control checks the kind of the process target content (S3130). If the process target content is the data indicating information of terms (i.e., text data) (S3130: YES), the control displays the process target content within the term display area of the contents providing window (S3140), and proceeds to S3200. If another content have been displayed in the term display area, the control erases the previous display and display the process target content prior to the other.

If the type of the process target contents is data of animating images (animating image data) (S3130: NO, S3150: YES), the control registers the process target contents (path name) and the “source generation time information” of the record of the search result management table corresponding to the process target contents with an animating image data queue (S3160), and then the control proceeds to S3200. The contents registered with the animating image data queue are written in the output buffer subsequently (in the registered order) so that the animating image is reproduced in the animation reproduction area of the contents providing window and the sound output from the sound output unit 79 is performed. Thereby, the reproduction of the animating image in the animated image reproduction area and sound output from the sound output unit 79 are started. It should be noted that if the output buffer has stored some other contents, the control overwrites the process target contents in the output buffer so that the process target contents are processed prior to the other contents.

If the type of the process target contents is the sound data (S3150: NO, S3170: YES), the control outputs the sound, which is the contents, through the sound output unit 79 (S3180), and the control proceeds to S3200. It should be noted that if the output of other contents has been started, the control stops the sound output, and the reproduces the sound of the process target contents prior to the other contents.

If the type of the process target contents is data representing information other than the terms (i.e., the type is text data and/or image data) (S3170: NO), the control registers the process target contents (path name thereof) and the “source generation time information” of the record of the search result management table corresponding to the process target contents with the display queue in a related manner (S3190), and proceeds to S3200. The contents thus registered with the display queue are subsequently transmitted to the output buffer for displaying text/image within the text/image displaying area of the contents providing window displayed on the display unit 77 by the control unit 71, thereby the contents is displayed in the text/image display are as scrolled upward. It should be noted that, according to the second illustrative embodiment, when the other contents are stored in the output buffer, the process target contents are displayed in the text/image display area such that the image of the process target contents is arranged below the image of the previously stored contents, and will be scrolled up as the image of the previously stored contents scrolls up.

After the display/reproduction of respective contents are started, the control updates the “output set information” of the record of the search result management table corresponding to the process target contents to “TRUE” which means the end of output (S3200). Then, the control deletes the contents (and the source generation time information) whose source generation time is prior to the current time by a predetermined period from the animating image production queue and display data queue (S3210). Thereafter, the control returns to S3110 and pauses until contents which have not yet been output are stored in the storage unit 73 in the readout procedure.

With the contents providing system according to the second illustrative embodiment, the information collect/analyze device 70 collects the text data representing the text displayed on the display unit 43 in accordance with the user's operation of the input unit 41 of the PC 30, the text data converted from the sound data input/output through the sound input unit 61 and sound output unit 63 of the telephone device 50 (S180 of FIG. 3, S260 of FIG. 4, S310-S330 of FIG. 5).

From the text data thus collected, keywords serve as search keys when contents are searched are extracted (S430, S450 of FIG. 7). The information collect/analyze device 70 transmit queries, which are generated based on the search keys, to the server (e.g., the information search server 20). When the query is received, a searching program for searching the contents is executed on the server side (S2620 of FIG. 20). Then, the information collect/analyze device 70 receives the contents searched and transmitted by the server (S2690, S2700 of FIG. 20). The contents are displayed/reproduced on the contents providing window displayed on the display unit 77 (S3140, S3160, S3180, S3190 of FIG. 24).

When the information collect/analyze device 70 transmits the query to start up a searching program on the server side, if the number of searching programs currently being executed is equal to or greater than a predetermined number (in the illustrative embodiment, all), the information collect/analyze device 70 issues a stop command to stop one program having the earliest startup time (i.e., the program started firstly among the plurality of programs being executed).

The searching program which was started at the earliest time was started when a certain text was input/output through the user interface 40 or 60 of the PC 30 or telephone device 50. Thus, a relatively long period has been passed since the searching program having the earliest startup time was started. The contents searched by such a searching program may not be so interesting for the user since a relatively long time period has passed since the text was input/output through the user interface 40 or 60.

Therefore, by issuing the stop command to stop the searching program having the earliest startup time (specifically, the searching procedure that employs the searching program), it becomes possible to prevent a condition where the contents which may not meet the current user's interest are provided at a later time. As a result, it becomes possible that contents in which the user may be very much interested are provided at an appropriate timing.

In the above-described illustrative embodiment, when the information collect/analyze device 70 operates to start up the searching program on the server side, if all the searching programs corresponding to the records registered with the searching program table are being executed, the searching program firstly started (i.e., the searching procedure that uses the firstly-started searching program) is stopped (S2532, S2540 of FIG. 18).

Specifically, a procedure of checking the number of searching programs currently executed (S2526, S2536 of FIG. 18) and a procedure of stopping the firstly-started searching program (S2532, S2540 of FIG. 18) are executed for each of the type of the searching programs. Therefore, for each type searching programs, the firstly-executed one can be stopped.

Next, the contents providing system according to a third illustrative embodiment will be described. Since the most part of the third embodiment is similar to the second one, and only some parts of procedures are different. Therefore, the difference will be describe in detail.

The search control procedure according to the third embodiment is similar to that of according to the second embodiment except for some steps. Therefore, in the following description, the steps same as those of the second embodiment are remained to have the same step number, while different steps are assigned with different step numbers, which are described in detail.

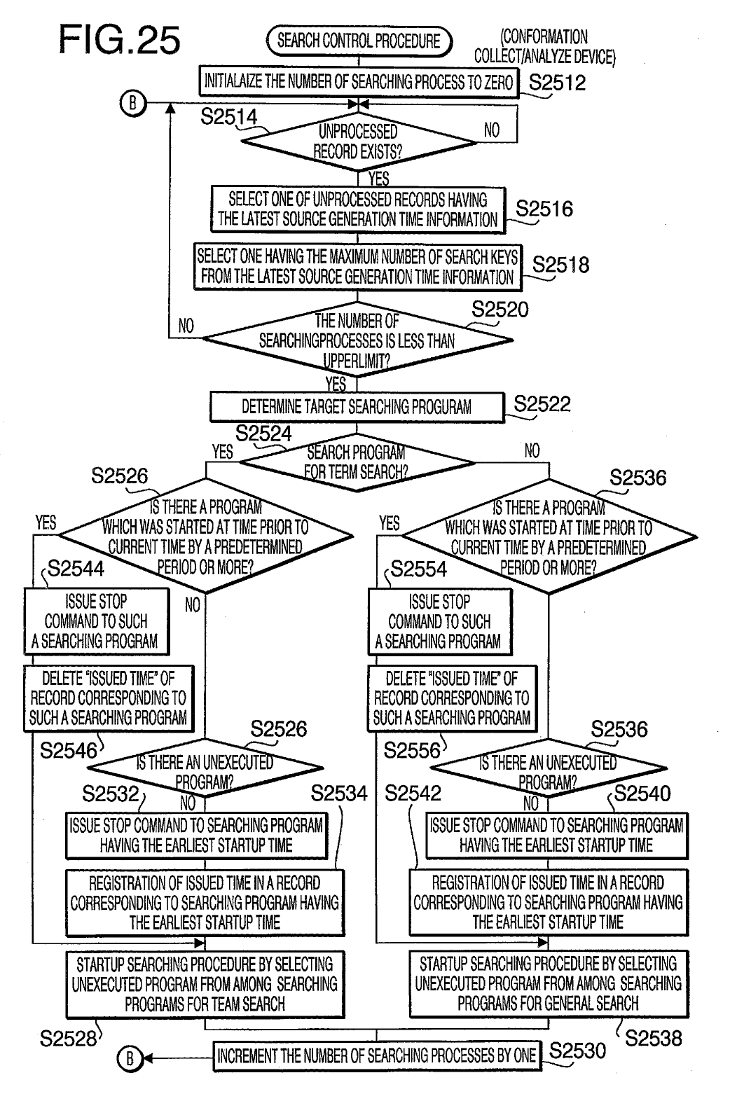

FIG. 25 shows a flowchart of the search control procedure according to the third illustrative embodiment. When the search control procedure is started, S2512-S2522 are executed. If the searching program determined in S2522 is for the “term search” (S2524: YES), the control judges whether, among the searching programs for “term search” corresponding to the records registered with the searching program table, there exists a searching program whose corresponding record includes “issued time” which is earlier than the current time by a predetermined amount (five minutes, according to the third embodiment) (S2542).

If the control determines that the searching program of which the time represented by the “issued time” is earlier than the current time by the predetermined amount does not exist (S2542: NO), the control proceeds to S2526. If such a searching program exists (S2542: YES), the control issues the stop command to the search program (S2544) as in S2532, deletes the registered contents of the “issued time” in the record corresponding to the searching program (S2546), and proceeds to S2528.

If the searching program determined in S2522 is for the “general search” (S2524: NO), the control judges whether, among the searching programs for the “general search” corresponding to the records registered with the searching program table, there exists a searching program of which corresponding record includes the “issued time” which is earlier than the current time by a predetermined amount (five minutes, in the embodiment) (S2552).

If there does not exist the searching program of which the time represented by the “issue time” is earlier than the current time by the predetermined amount (S2552: NO), the control proceeds to S2536. If there exists such a searching program (S2552: YES), the control issues the stop command to the searching program (S2554), deletes the content of the “issued time” of the record corresponding to the searching program (S2556), and proceeds to S2538.

According to the third embodiment, in addition to the advantages and effects obtained by the second embodiment, the following effects can be obtained.

The information collect/analyze device 70 is configured to issue the stop command for stopping the searching program (specifically, the procedure using the searching program) which has been executed for predetermined period or more (i.e., the time represented by the “issue time” of the corresponding record is earlier than the current time by a predetermined period) (S2542-S2546 of FIG. 25, S2552-S2556 of FIG. 25).

As above, when the searching program has been executed for the predetermined period or more, a relatively long period has passed since the information triggering the searching program was input/output (e.g., text is input/output through the user interfaces 40 and 60 of the PC 30 and telephone device 50). Therefore, the contents searched and collected may not be so interesting for the user as a relatively long period has passed since the text input/output through the user interfaces 40 and 60 was done.

As described above, by stopping the searching program which has been executed for a predetermined period or more with the stop command, it is possible to avoid a condition where the contents which would not meet the user's requirement are provided at a later stage. As a result, the contents the user may be interested in can be provided at an appropriate timing.

It should be noted that the above described embodiments can be modified in various ways without departing from aspects of the invention.

For example, in the illustrative embodiments, the PC investigating procedure (FIG. 3) is executed by the investigation unit 35 of the PC 30. This may be modified such that the PC investigating procedure is executed by the control unit 31 of the PC 30.

Further, in the illustrative embodiments above, the telephone investigating procedure (FIG. 4) is executed by the investigation unit 55 of the telephone device 50. This configuration may be modified such that the telephone investigating procedure is executed by the control unit 51 of the telephone device 50.

In the illustrative embodiments, the keyword extracting procedure (FIG. 7) is executed by the analyzing unit 81 of the information collect/analyze device 70. This configuration may be modified such that the keyword extracting procedure is executed by the control unit 71 of the information collect/analyze device 70 in parallel with the other procedures.

In the illustrative embodiments, the searching procedure (FIG. 9 or 18) is executed by the searching unit 83 of the information collect/analyze device 70. This configuration may be modified such that the searching control procedure is executed by the control unit 71 of the information collect/analyze device 70 in parallel with the other procedures.

In the illustrative embodiments, the searching procedure (FIG. 11 or 20) is executed by the searching unit 83 of the information collect/analyze device 70. This configuration may be modified such that the searching control procedure is executed by the control unit 71 of the information collect/analyze device 70 in parallel with the other procedures.

In the illustrative embodiments, the readout control procedure (FIG. 13 or 22) is executed by the readout unit 85 of the information collect/analyze device 70. This configuration may be modified such that the searching control procedure is executed by the control unit 71 of the information collect/analyze device 70 in parallel with the other procedures.

In the second illustrative embodiment, when the searching program is to be started on the server side, if all the searching programs corresponding to the records registered with the searching table are being executed, the firstly-executed searching program is stopped (S2532, S2540 of FIG. 18). This procedure may be modified such that, if a predetermined number of or more searching programs are being executed, the firstly-executed searching program is stopped.

Optionally, instead of stopping only one searching program (i.e., the firstly-executed, or oldest program), a plurality of searching programs started at the earliest stages may be stopped.

In the second embodiment, the criteria to determine whether the previously executed program is to be stopped is the number of executed files. This number may be varied depending on the type of the searching program. That is, the searching program may be stopped in accordance with different criteria.

In the third illustrative embodiment, when the searching program is started on the server side, a program whose elapsed time (i.e., a period elapsed after execution of the program) is equal to or greater than the predetermined period is stopped. The timing when the program stopped need not be limited to a timing when the searching program is to be executed, but any other timing would be used.

For example, every time when a keyword is obtained from the PC 30 and the telephone device 50, a searching program of which the elapsed time period after its execution is greater than the predetermined period ma be stopped. In this case, in the source information registration procedure shown in FIG. 5, after execution of S330, processes corresponding to S2542, S2552 of FIG. 25, S2544, S2546 of FIG. 25, and S2554, S2556 are executed (regardless of type of the searching program) are executed, and the control returns to S310. According to such a configuration, every time when the search key is obtained from the PC 30 or the telephone device 50, a searching program having been executed for more than the predetermined period can be stopped.

According to the third embodiment, the criterion of the “predetermined period” for determining whether the searching program is to be stopped may be set such that the user may not be so interested in the search key after elapse of the predetermined period, and concrete value of the predetermined period may be determined depending on respective cases.

It should be noted that, depending on the type of the searching programs, different procedures are executed. Therefore, in certain cases, the “predetermined period” may be varied depending on the types of the searching programs. That is, in certain cases, different “predetermined periods” are used for different types of searching programs. For example, in FIG. 25, the “predetermined periods” in S2542 and in S2552 may be differentiated. With such a configuration, in accordance with the type of the searching program, different criterion is applied to stop the searching program.

In the third embodiment described above, the information collect/analyze device 70 is configured to limit the number of searching programs executed in parallel. This configuration may be changed so that the number of procedures for providing the contents may be restricted.

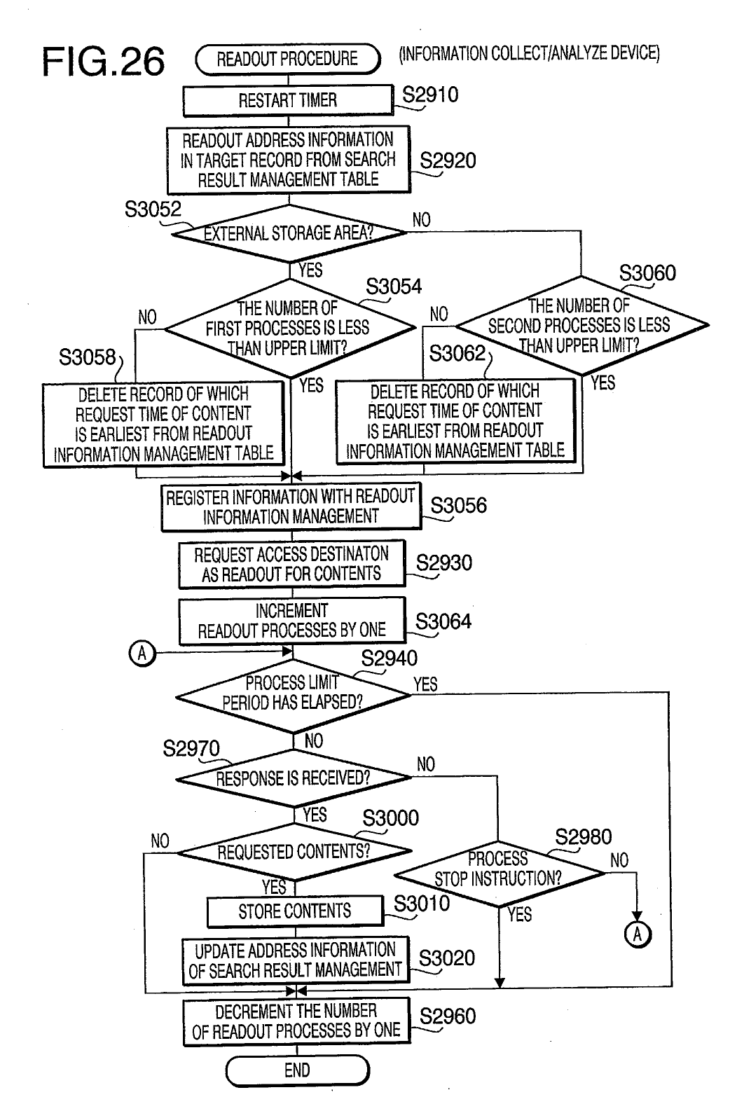

For this purpose, the numbers of the first and second processes are reset in S2310 of FIG. 22, and S2830 and “S2860 are not executed. Further, FIG. 23 should be modified as shown in FIG. 26.

As shown in FIG. 26, after the “address information” is read in S2920, the control judges whether the access destination designated by the address information is an external storage area (database) (S3052). If the control determines that the access destination is the external storage area (S3052: YES), the control judges whether the number of the first processes is less than a predetermined upper limit (which is two according the embodiment) in S3054.

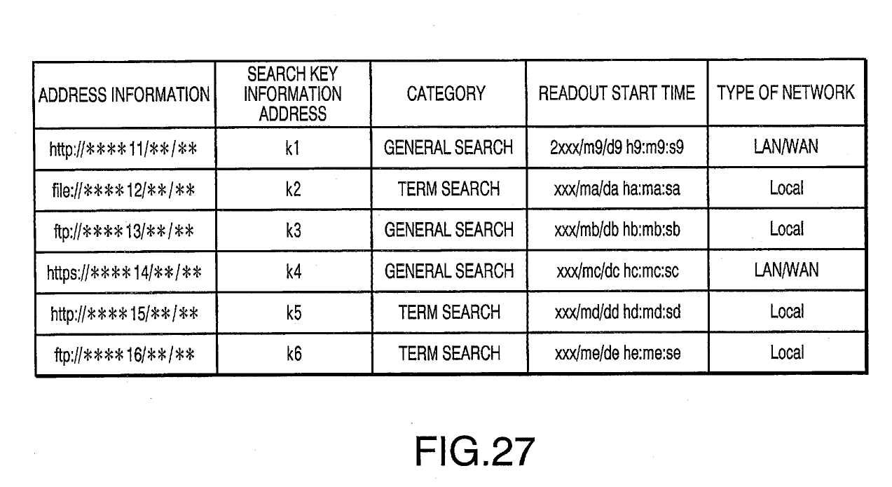

If the number of the first processes is less than the predetermined upper limit (S3054: YES), the control registers the “address information”, “search key address”, “category information”, a type of (i.e., whether inner or outer) the access destination designated by the address information, and the current time with the readout information management table (S3056). Then, the control proceeds to S2930 and requests for the contents. FIG. 27 shows an example of the readout information management table. As shown in FIG. 27, the readout information management table stores records each including items of “address information”, “search key address”, “category information”, “readout start time information”, “access destination type”. In S3056, registration of the information is executed. It should be noted that, in the “readout start time information”, the current time is stored, and in “access destination type”, a value “LAN/WAN” that indicates the external storage area.

If the number of first processes is equal to or greater than the predetermined upper limit (S3054: NO), the control deletes a record of which the “access destination type” indicates value representing the outer storage, and the time when requesting the access destination for the contents is the oldest (S3058). Then, the control proceeds to S3056, and registers the information with the readout information management table. Then, the control proceeds to S2930 and requests for the contents.

If the control determines that the access destination is the internal storage area (database) (S3052: NO), the control judges whether the number of second processes is less than a predetermined upper limit (which is four according to the illustrative embodiment) in S3060. It should be noted that the upper limit for the second process is set greater than the upper limit for the first process.

If the number of the second processes is less than the predetermined upper limit (S3060: YES), similar to S3056, the control registers the “address information”, “search key address”, “category information”, the type of the access destination represented by the address information and the current time with the readout information management table (S3062). Then, the control proceeds to S2930 and requests for the contents. It should be noted that the control registers a value “Local” representing the inner storage area as the “access destination type”.

If the number of the second processes is equal to or greater than the predetermined upper limit (S3060: NO), the control deletes a record whose “access destination type” is the inner storage, and the time when the access destination represented by the “address information” is the earliest (i.e., the record having the longest elapsed time). Then, the control proceeds to S3056, registers information with the readout information management table, proves to S2930 and requests for the contents.

After requesting for the contents, if the access destination is the external storage, the control increments the number of first readout processes by one. If the access destination is the inner storage, the control increments the number of the second readout processes by one (S3064). Then, the control proceeds to S2940.

If, in S2960, the access destination is the external storage area, the control decrements one from the number of first readout processes, while if the access destination is the internal storage area, the control decrements one from the number of the second readout processes, and finishes the readout procedure.

In the above configuration, depending on whether the access destination is the external storage of the internal storage, the upper limit of the number of the processes is different. It should be noted that the upper limit corresponding to the internal storage area is greater value. It is because, if the access destination is inside, there are a little factors (e.g., network traffic) that affect on the process time for search. Therefore, the search may be executed within an average (general) search period, and readout of the contents may be executed in a relatively short period.

Since the upper limit of the number of processes when the access destination is external is greater, while the upper limit is greater when the access destination is inside, more contents may be provided when the access destination is inside. Such contents are searched and read out within a relatively short period, and meet the changeable user's interest.

What is claimed is:

1. A contents providing system that provides contents, the system comprising:
an information obtaining unit that obtains at least one of input information input to a user interface of a client device and output information output from the user interface;
a content searching unit that searches for contents in accordance with the information obtained by the information obtaining unit;
a content output control unit that outputs a content searched by the content searching unit to an output unit, the output unit providing the content to a user of the client device; and
a content identifying unit that identifies one of the contents searched by the content searching unit, each of the contents having executed a predetermined process, the content identifying unit identifies the content that has executed the predetermined process latest,
wherein the content output control unit outputs the content identified by the content identifying unit prior to other contents searched by the content searching unit.

2. The contents providing system, according to claim 1,
wherein the output control unit includes a display unit, and
wherein the content output control unit displays the content searched by the content searching unit on the display unit to provide the content to the user of the client device.

3. The contents providing system according to claim 2,
wherein the content output control unit displays the content identified by the content identifying unit differently from the other contents searched by the content searching unit.

4. The contents providing system according to claim 2,
wherein the content output control unit displays the contents searched by the content searching unit on the display such that the contents are arranged in an order in which execution of the predetermined process is latest to earliest.

5. The contents providing system according to claim 1,
further including a keyword extracting unit that extracts a keyword from the information obtained by the information obtaining system,
wherein the contents searching unit searches for contents corresponding to the keyword extracted by the keyword extracting unit.

6. The contents providing system according to claim 5,
wherein identifying unit identifies, among the contents searched by the content searching unit, a content from which a keyword was extracted by the keyword extraction unit latest.

7. The contents providing system according to claim 1,
further including time registering system configured to register a time when the predetermined process is executed during a process in which the contents searching unit searches the content in association with the content,
wherein the content identifying unit identifies the content corresponding to the time, which is registered by the time registering system, is closest to the current time.

8. An output control device, comprising:
a content output control unit that outputs a content which has been searched in accordance with a user's operation to provide the content to the user; and
a content identifying unit that identifies, from among the contents searched in accordance with the user's operation, a content to which the identifying operation is performed at a later order than the other contents,
wherein the content output control unit outputs the content identified by the content identifying unit prior to any other content searched in accordance with the user's operation.

9. A computer program product comprising computer readable instructions that cause a computer to execute the steps of:
obtaining at least one of input information with respect to a user interface provided to a client device and output information output by the user interface;
searching for contents corresponding to the information obtained by the obtaining step;
outputting the contents searched by the searching step to the output unit to provide the contents to the user of the client device; and
identifying a content for which identifying operation is executed later than the identifying operation for other contents from among the contents searched by the searching step,
wherein the outputting step outputs the content identified by the identifying step prior to other contents searched by the searching step.

10. A contents providing system, comprising:
an information obtaining unit that obtains at least one of input information input to a user interface of a client device and output information output from the user interface;
a search procedure starting unit that subsequently starts searching procedures to search a predetermined database for contents corresponding to information obtained by the information obtaining unit;
a content output control unit that outputs a content searched by the search procedure starting unit to an output unit, the output unit providing the content to a user of the client device; and
a stopping unit that stops at least one search procedure that was started earliest among executed search procedures when the information obtaining unit obtains the information and a predetermined number or more of search procedures are being executed.

11. The contents providing system according to claim 10,
wherein the search procedures starting unit starts, form among a plurality of kinds of the search procedures, one corresponding to the information obtained by the information obtaining unit, and
wherein the stopping unit stops at least one search procedure that was started earliest among executed search procedures when the information obtaining unit obtains the information and a predetermined number or more of search procedures of the same kind are being executed.

12. The contents providing system according to claim 11,
wherein the predetermined number varies depending on the kinds of search procedures.

13. A contents providing system, comprising:
an information obtaining unit that obtains at least one of input information input to a user interface of a client device and output information output from the user interface;
a search procedure starting unit that subsequently starts searching procedures to search a predetermined database for contents corresponding to information obtained by the information obtaining unit;
a content output control unit that outputs a content searched by the search procedure starting unit to an output unit, the output unit providing the content to a user of the client device; and
an elapsed time investigating unit that investigates, for each of the searching procedure, an elapsed time after the searching procedure was started; and
a stopping unit that stops the searching procedure of which the elapsed time is equal to or greater than a predetermined period.

14. The contents providing system, according to claim 13,
wherein the stopping unit stops the searching procedure if the investigated elapsed time is equal to or greater than the predetermined period when the information obtaining unit obtains a subsequent piece of information.

15. The contents providing system according to claim 13,
wherein the search procedure starting unit starts one of a plurality of types of the search procedures corresponding to the information obtained by the information obtaining unit, and
wherein the predetermined period varies depending on the type of the search procedure.

16. An search control device for an output control device configured to include an information obtaining unit that obtains at least one of input information input to a user interface of a client device and output information output from the user interface, a search procedure starting unit that subsequently starts searching procedures to search a predetermined database for contents corresponding to information obtained by the information obtaining unit, a content output control unit that outputs a content searched by the search procedure starting unit to an output unit, the output unit providing the content to a user of the client device,
wherein the search control device comprising:
a stopping unit that stops at least one search procedure that was started earliest among executed search procedures when the information obtaining unit obtains the information and a predetermined number or more of search procedures are being executed.

17. A search control device for an output control device including an information obtaining unit that obtains at least one of input information input to a user interface of a client device and output information output from the user interface, a search procedure starting unit that subsequently starts searching procedures to search a predetermined database for contents corresponding to information obtained by the information obtaining unit, and a content output control unit that outputs a content searched by the search procedure starting unit to an output unit, the output unit providing the content to a user of the client device,
wherein the search control device comprising:
an elapsed time investigating unit that investigates, for each of the searching procedure, an elapsed time after the searching procedure was started; and
a stopping unit that stops the searching procedure of which the elapsed time is equal to or greater than a predetermined period.

18. A computer program product comprising a computer readable instructions that cause a computer to execute the steps of:
obtaining unit that obtains at least one of input information input to a user interface of a client device and output information output from the user interface;
subsequently starting searching procedures to search a predetermined database for contents corresponding to information obtained by the information obtaining step;
outputting a content searched to an output unit, the output unit providing the content to a user of the client device; and
stopping at least one search procedure that was started earliest among executed search procedures when the information obtaining step obtains the information and a predetermined number or more of search procedures are being executed.

19. A computer program product comprising a computer readable instructions that cause a computer to execute the steps of:
obtaining at least one of input information input to a user interface of a client device and output information output from the user interface;
subsequently starting searching procedures to search a predetermined database for contents corresponding to information obtained by the information obtaining step;
outputting a content searched by the searching step to an output unit, the output unit providing the content to a user of the client device; and
investigating, for each of the searching procedure, an elapsed time after the searching procedure was started; and
stopping the searching procedure of which the elapsed time is equal to or greater than a predetermined period.
